(19) United States
(12) Patent Application Publication
(10) Pub. No.: US 2026/0333857 A1
(43) Pub. Date: Oct. 22, 2026

(54) SEMICONDUCTOR DEVICE HAVING DIFFERENT INTERVALS BETWEEN CHANNEL LAYERS

(71) Applicant: SAMSUNG ELECTRONICS CO., LTD., Suwon-si (KR)

(72) Inventors: Min Yong JEONG, Suwon-si (KR); Uihui KWON, Suwon-si (KR); Jaemyeong KIM, Suwon-si (KR); Pilkwang KIM, Suwon-si (KR)

(73) Assignee: SAMSUNG ELECTRONICS CO., LTD., Suwon-si (KR)

(21) Appl. No.: 19/424,767

(22) Filed: Dec. 18, 2025

(30) Foreign Application Priority Data
Apr. 21, 2025 (KR) 10-2025-0051594

(51) Int. Cl. H10D 84/85; H10D 30/00; H10D 30/01; H10D 30/47; H10D 62/10; H10D 62/13; H10D 62/80; H10D 64/23; H10D 64/27; H10D 84/01; H10W 20/41; H10W 20/43

(52) U.S. Cl. CPC H10D 84/851; H10D 30/481; H10D 30/503; H10D 30/506; H10D 62/102; H10D 62/151; H10D 62/883; H10D 64/256; H10D 64/516; H10W 20/43; H10W 20/435; H10D 30/017; H10D 30/0191; H10D 84/0167

(57) ABSTRACT

The present invention provides a semiconductor device. The semiconductor device includes a well region in a substrate, a multi-channel layer on the well region, and the multi-channel layer including first, second, and third channel layers sequentially stacked in a vertical direction and apart from one another, a first gate insulating layer between the first channel layer and the well region, and a gate electrode overlapping the multi-channel layer. The gate electrode includes a first inner electrode between the first channel layer and the second channel layer, and an outer electrode on the third channel layer. An interval between the well region and the first channel layer is less than an interval between the first channel layer and the second channel layer.

### CROSS-REFERENCE TO RELATED APPLICATIONS

This U.S. non-provisional patent application claims priority under 35 U.S.C. § 119 to Korean Patent Application No. 10-2025-0051594, filed on Apr. 21, 2025 in the Korean Intellectual Property Office, the entire contents of which are hereby incorporated by reference.

### BACKGROUND

The embodiments of inventive concepts relate to a semiconductor device, and more particularly, to a semiconductor device including a field effect transistor.

The semiconductor device includes an integrated circuit consisting of metal-oxide-semiconductor field-effect transistors (MOS-FETs). To meet an increasing demand for the semiconductor device with a small pattern size and a reduced design rule, the MOS-FETs are being scaled down. The scale-down of the MOS-FETs may lead to deterioration in operation characteristics of the semiconductor device. Thus, a variety of studies are being conducted to overcome technical limitations associated with the scale-down of the semiconductor device and to realize high performance semiconductor devices.

### SUMMARY

The embodiments of the inventive concepts relate to a semiconductor device with improved electrical characteristics and reliability.

The embodiments of the inventive concepts relate to a method of manufacturing a semiconductor device with improved electrical characteristics and reliability.

A semiconductor device according to some embodiments of the inventive concept may include a well region in a substrate, a multi-channel layer on the well region, and the multi-channel layer including first, second, and third channel layers sequentially stacked in a vertical direction and spaced apart from one another, a first gate insulating layer between the first channel layer and the well region, and a gate electrode overlapping the multi-channel layer, in which the gate electrode includes an inner electrode between the first channel layer and the second channel layer, and an outer electrode on the third channel layer, and an interval between the well region and the first channel layer is less than an interval between the first channel layer and the second channel layer.

A semiconductor device according to some embodiments of the inventive concept may include a well region in a substrate, a multi-channel layer on the well region, and the multi-channel layer including a plurality of channel layers sequentially stacked in a vertical direction and spaced apart from one another, the plurality of channel layers including a first channel layer, which is a lowermost layer among the plurality of channel layers, a first gate insulating layer between the well region and the first channel layer, a gate electrode overlapping the multi-channel layer, and a gate insulating film between the multi-channel layer and the gate electrode, wherein at least one interval between the plurality of channel layer differs from remaining intervals between the plurality of channel layers.

A semiconductor device according to some embodiments of the inventive concept may include a well region in a substrate, a multi-channel layer on the well region and including first, second, and third channel layers sequentially stacked in a vertical direction and spaced apart from one another, source/drain patterns on both sides of the multi-channel layer, a gate electrode overlapping the multi-channel layer, a gate insulating film between the multi-channel layer and the gate electrode, a first gate insulating layer between the first channel layer and the well region, and a second gate insulating layer between a second channel layer and a third channel layer, in which the gate electrode comprises an inner electrode between the first channel and the second channel layer, and an outer electrode on the third channel layer, and an interval between the first channel layer and second channel layer is greater than an interval between the second channel layer and the third channel layer.

### BRIEF DESCRIPTION OF THE DRAWINGS

FIGS. 1, 2, and 3 are conceptual diagrams for describing logic cells of a semiconductor device according to embodiments of the inventive concept.

FIG. 4 is a plan view for describing a semiconductor device according to embodiments of the inventive concept.

FIGS. 5A, 5B, 5C, and 5D are diagrams illustrating a semiconductor device according to embodiments of the inventive concept, and are cross-sectional views taken along line A-A′, line B-B′, line C-C′, and line D-D′ in FIG. 4.

FIG. 6A is an enlarged view of the X portion of FIG. 5A.

FIG. 6B is an enlarged view of the Y portion of FIG. 5D.

FIGS. 7A and 7B are diagrams illustrating a semiconductor device according to embodiments of the inventive concept, and are cross-sectional views taken along line A-A′ and line D-D′ in FIG. 4.

FIGS. 8A and 8B are diagrams illustrating a semiconductor device according to embodiments of the inventive concept, and are cross-sectional views taken along line A-A′ and line D-D′ in FIG. 4.

FIGS. 9A, 9B, 10A, 10B, 10C, 11A, 11B, 11C, 11D, 12A, 12B, 13A, 13B, 14A, 14B, 14C, and 14D are diagrams for describing a method of manufacturing a semiconductor device according to embodiments of the inventive concept.

### DETAILED DESCRIPTION

Example embodiments of the inventive concepts will now be described more fully with reference to the accompanying drawings, in which example embodiments are shown.

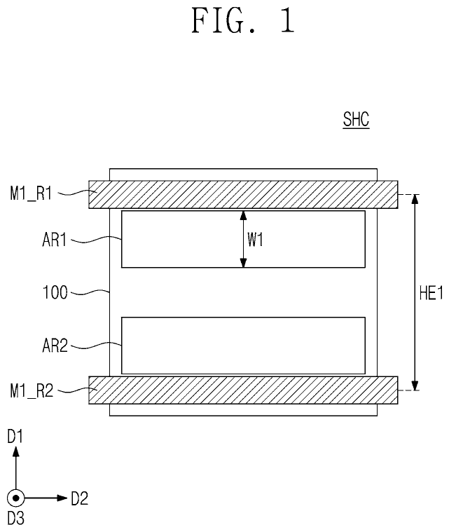

FIGS. 1 to 3 are conceptual diagrams for describing logic cells of a semiconductor device according to embodiments of the inventive concept.

Referring to FIG. 1, a single height cell SHC may be provided. For example, a first power line M1_R1 and the second power line M1_R2 may be provided on a substrate 100. According to embodiments, the first power line M1_R1 may be a ground line, and the second power line M1_R2 may be a power line.

The single height cell SHC may be defined between the first power line M1_R1 and the second power line M1_R2. The single height cell SHC may include one first active region AR1 and one second active region AR2. One of the first and second active regions AR1 and AR2 may be a PMOSFET region, and the other of the first and the second active regions AR1 and AR2 may be an NMOSFET region. That is, the single height cell SHC may have a CMOS structure provided between the first power line M1_R1 and the second power line M1_R2.

Each of the first and second active regions AR1 and AR2 may have a first width W1 in a first direction D1. The single height cell SHC may have a first height HE1 in the first direction D1. The first height HE1 may be substantially equal to a distance (e.g., pitch) between the first power line M1_R1 and the second power line M1_R2.

The single height cell SHC may constitute one logic cell. In this description, the logic cell may mean a logic device such as AND, OR, XOR, XNOR, and inverter, that performs a specific function. For example, the logic cell may include transistors for constituting a logic device and wiring lines that electrically connect the transistors to each other.

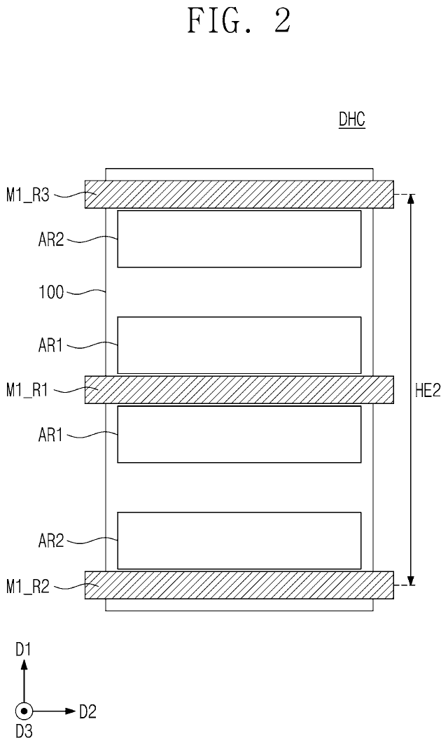

Referring to FIG. 2, a double height cell DHC may be provided. For example, a first power line M1_R1, a second power line M1_R2, and a third power line M1_R3 may be provided on a substrate 100. The first power line M1_R1 may be disposed between the second power line M1_R2 and the third power line M1_R3. According to embodiments, the second and third power lines M1_R2 and M1_R3 may be ground lines, and the first power line M1_R1 may be a power line.

The double height cell DHC may be defined between the second power line M1_R2 and the third power line M1_R3. The double-height cell DHC may include two first active regions AR1 and two second active regions AR2.

One of the two second active regions AR2 may be adjacent to the second power line M1_R2. The other of the two second active regions AR2 may be adjacent to the third power line M1_R3. The two first active regions AR1 may be adjacent to the first power line M1_R1. In a plan view, the first power line M1_R1 may be disposed between the two first active regions AR1.

The double height cell DHC may have a second height HE2 in the first direction D1. The second height HE2 may be about twice the first height HE1 of FIG. 1. The two first active regions AR1 of the double-height cell DHC may function as one active region.

In this description, the double height cell DHC may be defined as a multi-height cell. For example, the multi-height cell may include a triple height cell whose cell height is about three times that of the single height cell SHC.

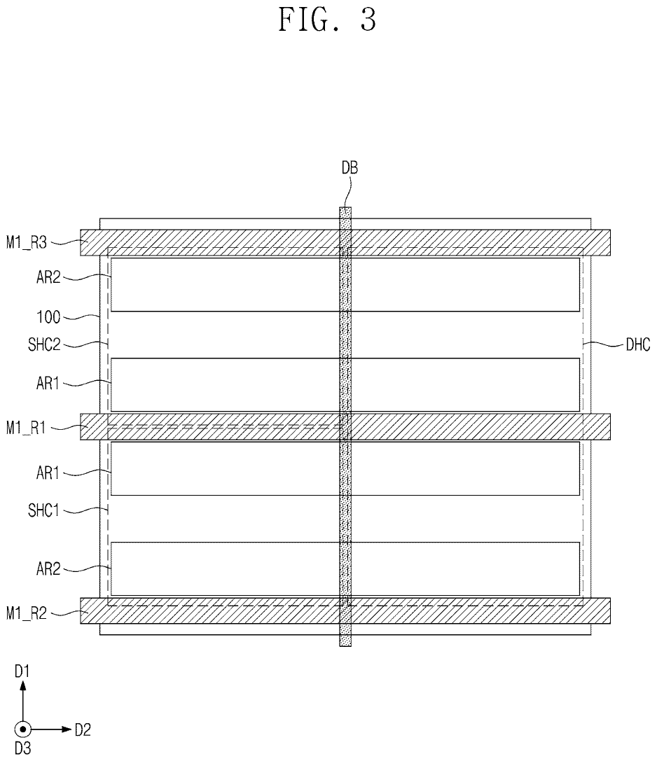

Referring to FIG. 3, a first single height cell SHC1, a second single height cell SHC2, and a double height cell DHC may be provided on a substrate 100 in two dimensions. The first single height cell SHC1 may be disposed between the first and second power lines M1_R1 and M1_R2. The second single height cell SHC2 may be disposed between the first and third power lines M1_R1 and M1_R3. The second single-height cell SHC2 may be adjacent to the first single-height cells SHC1 in the first direction D1.

The double height cell DHC may be disposed between the second and third power lines M1_R2 and M1_R3. The double height cell DHC may be adjacent to the first and second single height cells SHC1 and SHC2 in the second direction D2.

A separation structure DB extending in the first direction D1 may be provided between the first single height cell SHC1 and the double height cell DHC, and between the second single height cell SHC2 and the double height cell DHC. The separation structure DB may electrically separate active regions of the double height cell DHC and active regions of each of the first and second single height cells SHC1 and SHC2.

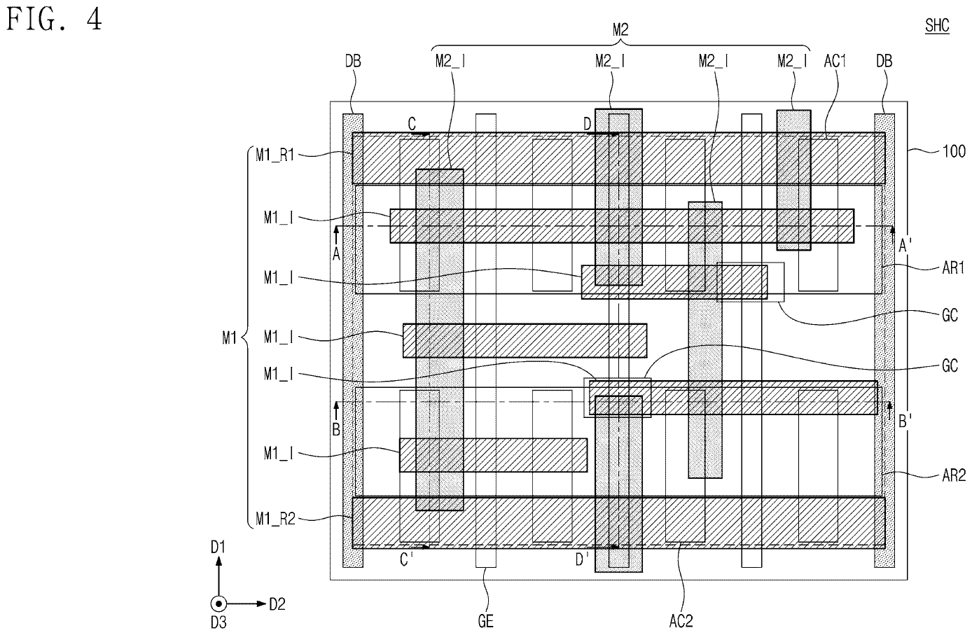

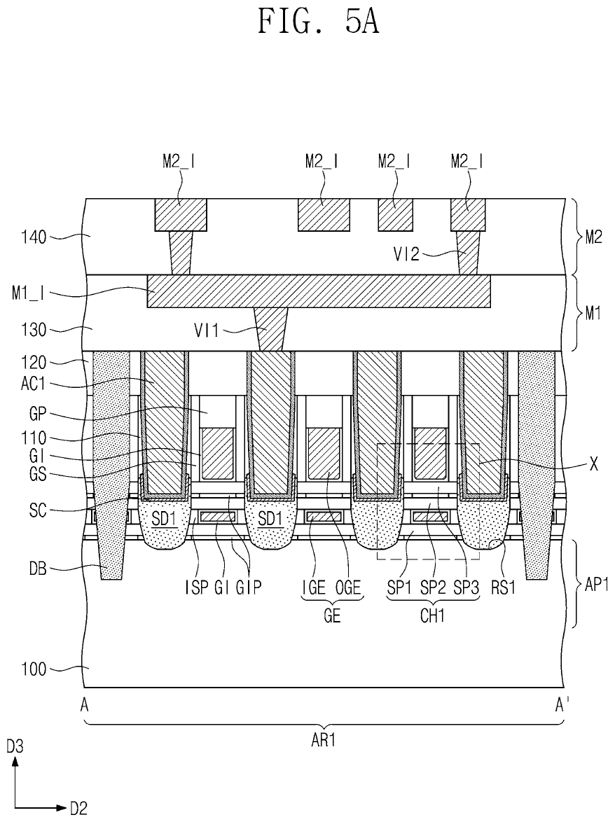

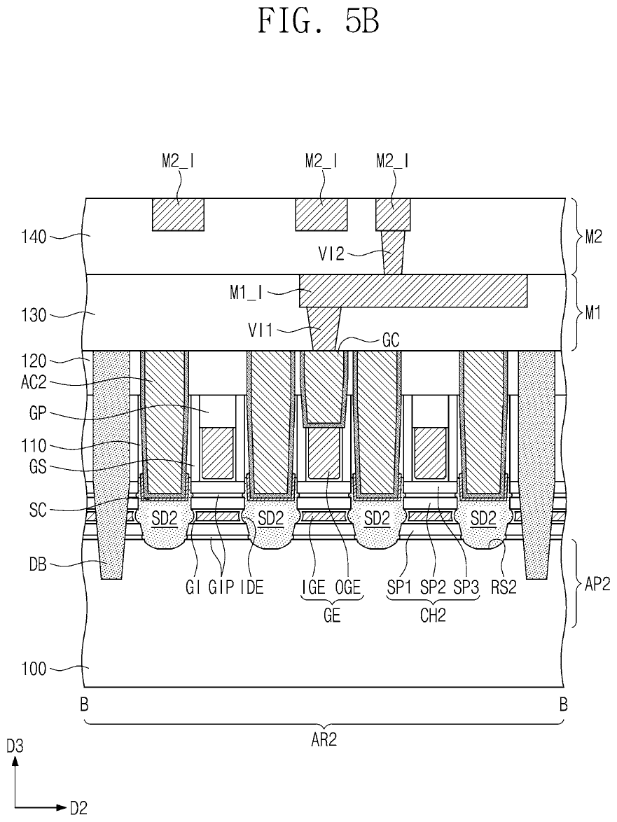

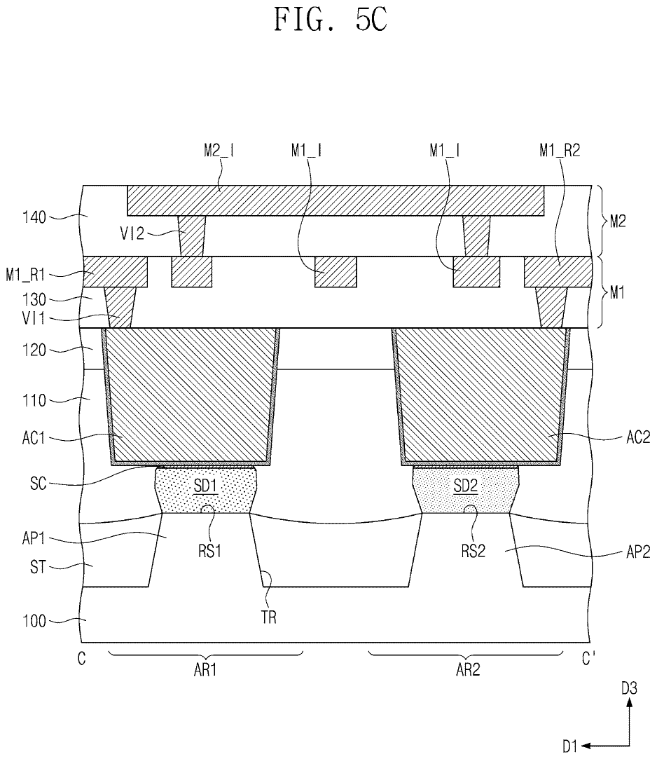

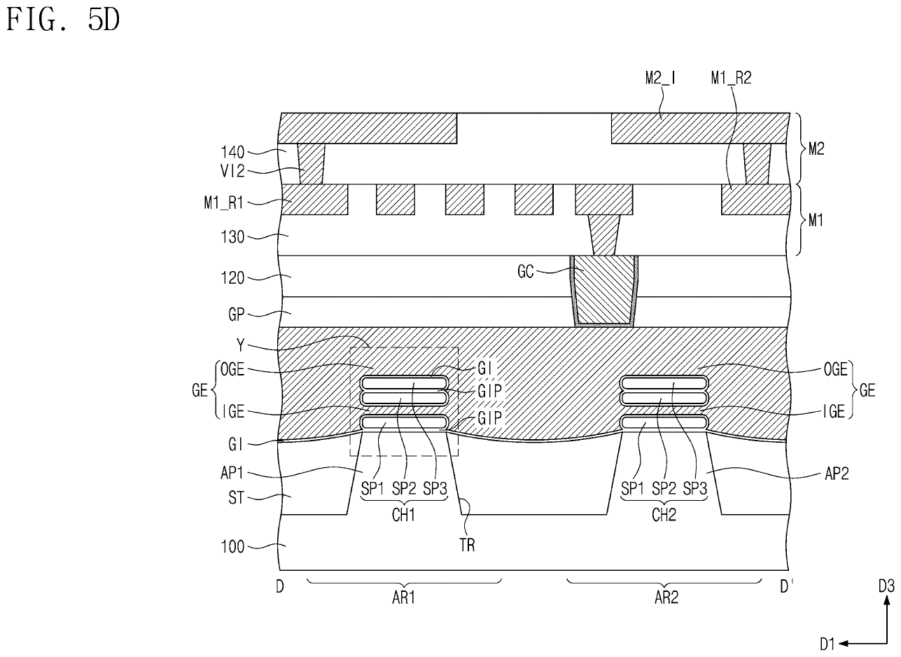

FIG. 4 is a plan view for describing a semiconductor device according to embodiments of the inventive concept. FIGS. 5A to 5D are diagrams illustrating a semiconductor device according to embodiments of the inventive concept, and are cross-sectional views taken along line A-A′, line B-B′, line C-C′, and line D-D′ in FIG. 4.

Referring to FIG. 4 and FIGS. 5A to 5D, a single height cell SHC may be provided on a substrate 100. Transistors constituting a logic circuit may be disposed on the single height cell SHC. The substrate 100 may be a semiconductor substrate including silicon, germanium, silicon-germanium, or the like, or may be a compound semiconductor substrate. For example, the substrate 100 may be a silicon substrate.

The substrate 100 may include a first active region AR1 and a second active region AR2. The first active region AR1 and the second active region AR2 may be spaced apart from each other in a first direction D1. Each of the first and second active regions AR1 and AR2 may extend in a second direction D2. For example, the first active region AR1 may be an NMOSFET region, and the second active region AR2 may be a PMOSFET region.

In this description, the first direction D1 and the second direction D2 may be parallel to a top surface or a bottom surface of the substrate 100. The first direction D1 and the second direction D2 may intersect with each other. A third direction D3 may be orthogonal to the top surface or the bottom surface of the substrate 100. The third direction D3 may intersect the first direction D1 and the second direction D2. For example, the first direction D1, the second direction D2, and the third direction D3 may be orthogonal to each other. The first direction D1 and the second direction D2 may be a horizontal direction, and the third direction D3 may be a vertical direction.

A first well region AP1 and a second well region AP2 defined by a trench TR may be provided on the substrate 100. The first well region AP1 may be provided on the first active region AR1, and the second well region AP2 may be provided on the second active region AR2. The first and second well regions AP1 and AP2 may extend in the second direction D2. For example, the first and second well regions AP1 and AP2 may be portions protruding in the third direction D3 as portions of the substrate 100. However, for convenience of description, the substrate 100 and the first and second well regions AP1 and AP2 may be defined by different configurations.

A device isolation layer ST may be provided on the substrate 100. The device isolation layer ST may fill the trench TR. The device isolation layer ST may cover side surfaces of the first and second well regions AP1 and AP2. For example, the device isolation layer ST may include silicon oxide. The device isolation layer ST may be spaced apart from the first and second multi-channel layers CH1 and CH2 which will be discussed below.

A first multi-channel layer CH1 may be provided on the first well region AP1. A second multi-channel layer CH2 may be provided on the second well region AP2. Each of the first and second multi-channel layers CH1 and CH2 may include a first channel layer SP1, a second channel layer SP2, and a third channel layer SP3 spaced apart from one another. The first to third channel layers SP1, SP2, and SP3 may be sequentially positioned in the third direction D3 on each of the first and second well regions AP1 and AP2. For example, the first to third channel layers SP1, SP2, and SP3 of each of the first multi-channel layer CH1 and the second multi-channel layer CH2 may be vertically stacked and spaced apart from one another.

Each of the first to third channel layers SP1, SP2, and SP3 may include silicon, germanium, and/or silicon-germanium. For example, each of the first to third channel layers SP1, SP2, and SP3 may include crystalline silicon, and more specifically, may include single crystal silicon.

A plurality of first source/drain patterns SD1 may be provided on the first well region AP1. The first source/drain patterns SD1 may be located in first recesses RS1 formed on an upper portion of the first well region AP1. The first source/drain patterns SD1 may be impurity regions having a first conductivity type (e.g., n-type). The first multi-channel layer CH1 may be positioned between the first source/drain patterns SD1 adjacent to each other in the second direction D2. For example, the first to third channel layers SP1, SP2, and SP3 that are vertically stacked and spaced apart from one another may electrically connect the first source/drain patterns SD1 adjacent to each other in the second direction D2.

A plurality of second source/drain patterns SD2 may be provided on the second well region AP2. The second source/drain patterns SD2 may be located in second recesses RS2 formed on an upper portion of the second well region AP2. The second source/drain patterns SD2 may be impurity regions having a second conductivity type (e.g., p-type). The second multi-channel layer CH2 may be positioned between the second source/drain patterns SD2 that are adjacent to each other in the second direction D2. For example, the first to third channel layers SP1, SP2, and SP3, that are sequentially stacked in the third direction D3 and spaced apart from one another, may electrically connect the second source/drain patterns SD2 adjacent to each other in the second direction D2.

The first and second source/drain patterns SD1 and SD2 may be epitaxial patterns formed by a selective epitaxial growth (SEG) process. For example, a top surface of each of the first and second source/drain patterns SD1 and SD2 may be higher than a top surface of the third channel layer SP3. Alternatively, the top surface of at least one of the first and second source/drain patterns SD1 and SD2 may be located at substantially the same level as the top surface of the third channel layer SP3.

According to embodiments, the first source/drain patterns SD1 may include the same semiconductor element (e.g., Si) as the substrate 100. Alternatively, the second source/drain patterns SD2 may include a semiconductor element (e.g., SiGe) having a lattice constant greater than that of the semiconductor element (e.g., Si) of the substrate 100. Accordingly, the second source/drain patterns SD2 adjacent to each other in the second direction D2 may provide a compressive stress to the second multi-channel layer CH2 therebetween. Sidewalls of the second source/drain patterns SD2 may have an uneven embossing shape. For example, the sidewalls of the second source/drain patterns SD2 may have a wavy profile. The sidewalls of the second source/drain patterns SD2 may protrude toward a gate electrodes GE which will be discussed below.

Gate electrodes GE may be provided on the first and second multi-channel layers CH1 and CH2. Each of the gate electrodes GE may extend in the first direction D1 and across the first and second multi-channel layers CH1 and CH2. Each of the gate electrodes GE may vertically overlap the first and second multi-channel layers CH1 and CH2. The gate electrodes GE may be spaced apart from each other in the second direction D2.

Each of the gate electrodes GE may include an inner electrode IGE and an outer electrode OGE. The inner electrode IGE of each of the gate electrodes GE may be positioned between the first channel layer SP1 and the second channel layer SP2 of each of the first and second multi-channel layers CH1 and CH2. The outer electrode OGE of each of the gate electrodes GE may be positioned on the third channel layer SP3 of each of the first and second multi-channel layers CH1 and CH2. For example, the gate electrodes GE may partially surround the first to third channel layers SP1, SP2, and SP3 of each of the first and second multi-channel layers CH1 and CH2.

According to embodiments, the gate electrodes GE may not be provided between the first channel layer SP1 of the first multi-channel layer CH1 and the first well region AP1, between the first channel layers SP1 of the second multi-channel layer CH2 and the second well region AP2, and between the second channel layer SP2 and the third channel layer SP3 of each of the first and second multi-channel layers CH1 and CH2. Accordingly, at least one of intervals between the first to third channel layers SP1, SP2, or SP3 of each of the first and second multi-channel layers CH1 and CH2 may be differ from remaining intervals between the first to third channel layers SP1, SP2, or SP3 of each of the first and second multi-channel layers CH1 and CH2.

A gate insulating film GI may be provided between the gate electrodes GE and the first multi-channel layer CH1 and between the gate electrode GE and the second multi-channel layer CH2. The gate insulating film GI may partially surround each of the first to third channel layers SP1, SP2, and SP3. In addition, the gate insulating film GI may cover a top surface of the device isolation layer ST under the gate electrodes GE. For example, the gate insulating film GI may include at least any one of silicon oxide, silicon oxynitride, a high dielectric material, a ferroelectric material, and a phase dielectric material. Alternatively, the gate insulating film GI may be formed of a multilayer structure including silicon oxide, silicon oxynitride, a high dielectric material, a ferroelectric material, a phase dielectric material, and the like.

Gate insulating layers GIP may be provided between the first channel layer SP1 of the first multi-channel layer CH1 and the first well region AP1, between the first channel layers SP1 of the second multi-channel layer CH2 and the second well region AP2, and between the second channel layer SP2 and the third channel layer SP3 of each of the first and second multi-channel layers CH1 and CH2. For example, the gate insulating layers GIP may be provided in a region where the gate electrodes GE are not provided. The gate insulating layers GIP may be formed simultaneously with the gate insulating film GI. A thickness of each of the gate insulating layers GIP may be greater than a thickness of the gate insulating film GI.

On the first active region AR1, inner spacers ISP may be provided between the gate electrodes GE and the first source/drain patterns SD1 and between the gate insulating layers GIP and the first source/drain patterns SD1. Each of the gate electrodes GE and the gate insulating layers GIP may be spaced apart from the first source/drain patterns SD1 with the inner spacers ISP therebetween. The inner spacers ISP may prevent leakage current generated from the gate electrodes GE.

A pair of gate spacers GS may be provided on both sidewalls of the outer electrode OGE of each of the gate electrodes GE. The gate spacers GS may extend along the gate electrodes GE in the first direction D1. For example, the gate spacers GS may include at least one of SiCN, SiCON, or SiN. Alternatively, the gate spacers GS may include a multilayer structure formed of at least two of SiCN, SiCON, or SiN.

According to an embodiment, the gate spacers GS may function as an etch stop layer when first and second active contacts AC1 and AC2 are formed in a subsequent process. In this case, each of the first and second active contacts AC1 and AC2 may be formed in a self-alignment manner by the pair of gate spacers GS.

Gate capping patterns GP may be provided on the gate electrodes GE. Each of the gate capping patterns GP may extend along the gate electrodes GE in the first direction D1. The gate capping patterns GP may include a material having etching selectivity with respect to the first and second interlayer insulating layers 110 and 120 which will be discussed below. For example, the gate capping patterns GP may include at least one of SiON, SiCN, SiCON, or SiN.

A first interlayer insulating layer 110 may be provided on the substrate 100. The first interlayer insulating layer 110 may cover the gate spacers GS and the first and second source/drain patterns SD1 and SD2. For example, the first interlayer insulating layer 110 may have a top surface positioned at substantially the same level as the gate capping patterns GP and the gate spacers GS.

The second to fourth interlayer insulating layers 120, 130, and 140 may be sequentially provided on the first interlayer insulating layer 110. The second interlayer insulating layer 120 may cover the first interlayer insulating layer 110, the third interlayer insulating layer 130 may cover the second interlayer insulating layer 120, and the fourth interlayer insulating layer 140 may cover the third interlayer insulating layer 130. For example, each of the first to fourth interlayer insulating layers 110, 120, 130, and 140 may include silicon oxide.

A pair of separation structures DB facing each other in the second direction D2 may be provided on both sides of the single height cell SHC. The separation structures DB may extend parallel to the gate electrodes GE in the first direction D1. Each of the separation structures DB may extend from the second interlayer insulating layer 120 toward the first and second well regions AP1 and AP2. The separation structures DB may penetrate the upper portion of each of the first and second well regions AP1 and AP2. For example, the separation structures DB may electrically separate an active region of the single height cell SHC from an active region of adjacent another cell.

First and second active contacts AC1 and AC2 may be provided to penetrate the first interlayer insulating layer 110 and the second interlayer insulating layer 120. The first active contacts AC1 may be connected with the first source/drain patterns SD1. The second active contacts AC2 may be connected with the second source/drain patterns SD2. Each of the gate electrodes GE may be positioned between the first and second active contacts AC1 and AC2 adjacent to each other in the second direction D2. In a plan viewed, each of the first and second active contacts AC1 and AC2 may have a bar shape extending in the first direction D1.

Metal-semiconductor compound layers SC may be provided between the first active contacts AC1 and the first source/drain patterns SD1 and between the second active contacts AC2 and the second source/drain pattern SD2. For example, the metal-semiconductor compound layers SC may include at least one of titanium-silicide, tantalum-silicide, tungsten-silicide, nickel-silicide, or cobalt-silicide.

Gate contacts GC may be provided to penetrate the second interlayer insulating layer 120 and the gate capping patterns GP to come into connection with the gate electrodes GE. In a plan viewed, the gate contacts GC may be disposed to overlap the first active region AR1 and the second active region AR2, respectively. For example, the gate contacts GC may be provided on the first well region AP1 and the second well region AP2.

A first metal layer M1 may be provided in the third interlayer insulating layer 130. The first metal layer M1 may include a first power line M1_R1, a second power line M1_R2, and first wiring lines M1_I. Each of the lines M1_R1, M1_R2, and M1_I of the first metal layer M1 may extend parallel to each other in the second direction D2. For example, the first wiring lines M1_I of the first metal layer M1 may be disposed between the first and second power lines M1_R1 and M1_R2. The first wiring lines M1_I of the first metal layer M1 may be spaced apart from each other in the first direction D1. A line-width of each of the first wiring lines M1_I may be less than a line-width of each of the first and second power lines M1_R1 and M1_R2.

The first metal layer M1 may further include first vias VI1. The first vias VI1 may be provided below each of the lines M1_R1, M1_R2, and M1_I of the first metal layer M1. The first and second active contacts AC1 and AC2 and the gate contacts GC may be electrically connected to the lines M1_R1, M1_R2, and M1_I of the first metal layer M1 through the first vias VI1.

A second metal layer M2 may be provided in the fourth interlayer insulating layer 140. The second metal layer M2 may include second lines M2_I. For example, the second lines M2_I may extend in the first direction D1 and may be spaced apart from each other in the second direction D2. The second metal layer M2 may further include a second vias VI2 provided below each of the second lines M2_I. The lines M1_R1, M1_R2, and M1_I of the first metal layer M1 and the second lines M2_I of the second metal layer M2 may be electrically connected to each other through the second vias VI2.

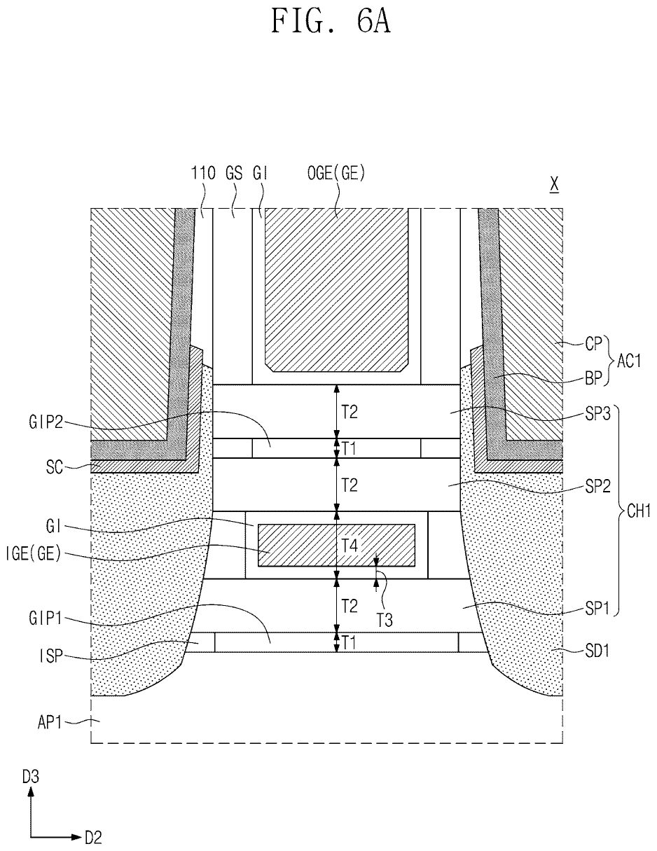

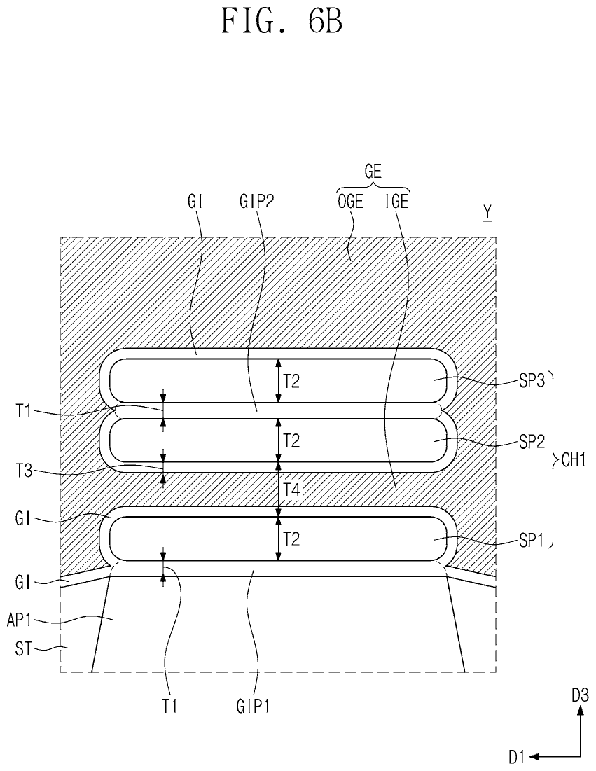

FIG. 6A is an enlarged view of the X portion of FIG. 5A. FIG. 6B is an enlarged view of the Y portion of FIG. 5D.

Referring to FIGS. 6A and 6B, A first multi-channel layer CH1 on a first well region AP1 may include a plurality of channel layers spaced apart from one another in the third direction D3. The plurality of channel layers may include a lowermost first channel layer SP1. For example, the first multi-channel layer CH1 may include a first channel layer SP1, a second channel layer SP2, and a third channel layer SP3 that are spaced apart from one another and sequentially stacked on the first well region AP1.

Gate insulating layers may be provided between the first well region AP1 and the first multi-channel layer CH1 and in the first multi-channel layer CH1. The gate insulating layers may include a first gate insulating layer GIP1 between the first channel layer SP1 and the first well region AP1 and a second gate insulating layer GIP2 between the second channel layer SP2 and the third channel layer SP3. The first gate insulating layer GIP1 may contact a bottom surface of the first channel layer SP1 and a top surface of the first well region AP1. The second gate insulating layer GIP2 may contact a top surface of the second channel layer SP2 and a bottom surface of the third channel layer SP3.

A gate electrode GE on the first multi-channel layer CH1 may include an inner electrode IGE between the first channel layer SP1 and the second channel layer SP2 and an outer electrode OGE on the third channel layer SP3. The gate electrode GE may be located on top and side surfaces of the first channel layer SP1. The gate electrode GE may be located on a bottom and side surfaces of the second channel layer SP2. The gate electrode GE may be located on a top and side surfaces of the third channel layer SP3. That is, the gate electrode GE may be located on three surfaces of each of the first to third channel layers SP1, SP2, and SP3. For example, the gate electrode GE may control the first multi-channel layer CH1 through three surfaces of each of the first to third channel layers SP1, SP2, and SP3.

A gate insulating film GI may be provided between the first multi-channel layer CH1 and the gate electrode GE. The gate insulating film GI may extend on a device isolation layer ST while covering the top and side surfaces of the first channel layer SP1. The gate insulating film GI may cover the bottom and the side surfaces of the second channel layer SP2. The gate insulating film GI may extend between the outer electrode OGE and gate spacers GS while covering the top and side surfaces of the third channel layer SP3.

The gate insulating film GI and the first and second gate insulating layers GIP1 and GIP2 may be simultaneously formed in one process. In the method of manufacturing a semiconductor device which will be discussed below, the gate insulating film GI and the first and second gate insulating layers GIP1 and GIP2 may be formed by a process of depositing an insulating material. That is, the gate insulating film GI and the first and second gate insulating layers GIP1 and GIP2 may include substantially the same insulating material. Accordingly, the gate insulating film GI and the first and second gate insulating layers GIP1 and GIP2 are connected to each other, and interfaces therebetween may be invisible.

In one embodiment, the first gate insulating layer GIP1 and the second gate insulating layer GIP2 may have substantially the same thickness, a first thickness T1, in the third direction D3. Each of the first to third channel layers SP1, SP2, and SP3 of the first multi-channel layer CH1 may have a second thickness T2 in the third direction D3. The gate insulating film GI may have a third thickness T3 in the third direction D3. The inner electrode IGE and the gate insulating film GI surrounding the inner electrode IGE may have a fourth thickness T4 in the third direction D3.

As used herein, the expression “substantially the same” may refer to having the same measurement value relative to other value(s) compared therewith, as will be appreciated by those of skill in the art, and allows for approximations, inaccuracies and limits of measurement under the relevant circumstances. In one or more aspects, the terms “substantially,” “about,” and “approximately” may provide an industry-accepted tolerance for their corresponding terms and/or relativity between items, such as a tolerance of ±1%, ±5%, or ±10% of the actual value stated, and other suitable tolerances.

According to an embodiment, each of the first to third channel layers SP1, SP2, and SP3 of the first multi-channel layer CH1 may be a two-dimensional semiconductor material. The two-dimensional semiconductor material may include at least any one of molybdenum disulfide (MoS₂), molybdenum diselenide (MoSe₂), tungsten disulfide (WS₂), tungsten diselenide (WSe₂), and bismuth selenium oxide (Bi₂O₂Se). In this case, the second thickness T2 of each of the first to third channel layers SP1, SP2, and SP3 may be relatively small. For example, the second thickness T2 may range from about 0.5 nm to about 3 nm.

The fourth thickness T4 of the inner electrode IGE and the gate insulating film GI may correspond to an interval between the first channel layer SP1 and the second channel layer SP2. The first thickness T1 of the second gate insulating layer GIP2 may correspond to an interval between the second channel layer SP2 and the third channel layer SP3. For example, the fourth thickness T4 may be greater than the first thickness T1. Therefore, the interval between the first channel layer SP1 and the second channel layer SP2 may be greater than the interval between the second channel layer SP2 and the third channel layer SP3. Accordingly, the intervals between the first to third channel layers SP1, SP2, and SP3 may differ from each other.

In the method of manufacturing a semiconductor device which will be discussed below, the gate insulating film GI and the first and second gate insulating layers GIP1 and GIP2 may be simultaneously formed. The gate insulating film GI may be formed as the first gate insulating layer GIP1 and the second gate insulating layer GIP2 by overlapping up and down between the first well region AP1 and the first channel layer SP1 and between the second channel layer SP2 and the third channel layer SP3. Therefore, the first thickness T1 of each of the first and second gate insulating layers GIP1 and GIP2 may be greater than the third thickness T3 of the gate insulating film GI. For example, the first thickness T1 may be greater than the third thickness T3 and less than or equal to twice the third thickness T3.

Each of the first source/drain patterns SD1 may be provided on both sides of the first multi-channel layer CH1. A bottom surface of each of the first source/drain patterns SD1 may be lower than a top surface of the first well region AP1. A top surface of each of the first source/drain patterns SD1 may be higher than the top surface of the third channel layer SP3. Since the gate electrode GE is not provided between the first well region AP1 and the first channel layer SP1 and between the second channel layer SP2 and the third channel layer SP3, a length in the third direction D3 from the top surface of the first well region AP1 to the top surface of the third channel layer SP3 may be reduced. Therefore, a height of each of the first source/drain patterns SD1 in the third direction D3 may be reduced. Accordingly, the semiconductor device of the inventive concept may be miniaturized.

Inner spacers ISP may be provided between the first gate insulating layer GIP1 and the first source/drain patterns SD1, between the second gate insulating layer GIP2 and the first source/drain patterns SD1, and between the inner electrode IGE of the gate electrode GE and the first source/drain patterns SD1. Each of the inner spacers ISP may be located on both sides of each of the first gate insulating layer GIP1, the second gate insulating layer GIP2, and the inner electrode IGE.

First active contacts AC1 may be provided to penetrate a first interlayer insulating layer 110 to come into connection with an upper portion of each of the first source/drain patterns SD1. Each of the first active contacts AC1 may include a conductive pattern CP and a barrier pattern BP surrounding the conductive pattern CP. The barrier pattern BP may cover sidewalls and a bottom surface of the conductive pattern CP. For example, the conductive pattern CP may include at least one of aluminum, copper, tungsten, molybdenum, or cobalt. The barrier pattern BP may be a metal including at least one of titanium, tantalum, tungsten, nickel, cobalt, or platinum or a metal nitride including at least one of titanium nitride, tantalum nitride, tungsten nitride, nickel nitride, cobalt nitride, or platinum nitride.

Metal-semiconductor compound layers SC may be located between the first source/drain patterns SD1 and the first active contacts AC1, respectively. Each of the metal-semiconductor compound layers SC may have a uniform thickness. For example, the metal-semiconductor compound layers SC may be formed from the barrier pattern BP of the first active contacts AC1 through a heat treatment process. The first active contacts AC1 may be electrically connected to the first source/drain patterns SD1 through the metal-semiconductor compound layers SC. The metal-semiconductor compound layers SC may reduce contact resistance between the first active contacts AC1 and the first source/drain patterns SD1.

According to embodiments, the gate electrode GE may not be provided between the first well region AP1 and the first channel layer SP1. The inner electrode IGE of the gate electrode GE may be further spaced apart from the first well region AP1 than the first channel layer SP1. Accordingly, a phenomenon of punch through and DIBL (Drain Induced Barrier Lowering) between the first source/drain patterns SD1 occurring on the first well region AP1 may be prevented.

In addition, the gate electrode GE may not be provided between the second channel layer SP2 and the third channel layer SP3. The inner electrode IGE may be minimally provided for controlling the first to third channel layers SP1, SP2, and SP3. Accordingly, a parasitic capacitance between the gate electrode GE and the first source/drain patterns SD1 and/or between the gate electrode GE and the first to third channel layers SP1, SP2, and SP3 may be reduced. Therefore, an electrical characteristic of the semiconductor device of the inventive concept may be improved.

According to an embodiment, the gate electrode GE may further include another inner electrode between the inner electrode IGE and the outer electrode OGE. For example, another inner electrode may be located between the second channel layer SP2 and the third channel layer SP3 of the first multi-channel layer CH1. In this case, the interval between the second channel layer SP2 and the third channel layer SP3 may be substantially the same as the interval between the first channel layer SP1 and the second channel layer SP2. The second gate insulating layer GIP2 may be omitted, and the gate insulating film GI may cover top and bottom surfaces and the side surfaces of the second channel layer SP2 and the top and bottom surfaces and side surfaces of the third channel layer SP3. The gate electrode GE may be located on the top and bottom surfaces and side surfaces of the second channel layer SP2 and the top and bottom surfaces and side surfaces of the third channel layer SP3. Therefore, the gate electrode GE may control the first multi-channel layer CH1 through four surfaces of each of the second channel layer SP2 and the third channel layer SP3.

The above-described structures of the first to third channel layers SP1, SP2, and SP3 of the first multi-channel layer CH1, the inner electrode IGE and the outer electrode OGE of the gate electrode GE, the gate insulating film GI, the first gate insulating layer GIP1, the second gate insulating layer GIP2, and the first active contacts AC1 may be equally applied to the second well region AP2 on the second active region AR2, the second multi-channel layer CH2, the gate electrode GE, the gate insulating film GI, the gate insulating layers GIP, and the second active contacts AC2 described with reference to FIGS. 5A to 5D.

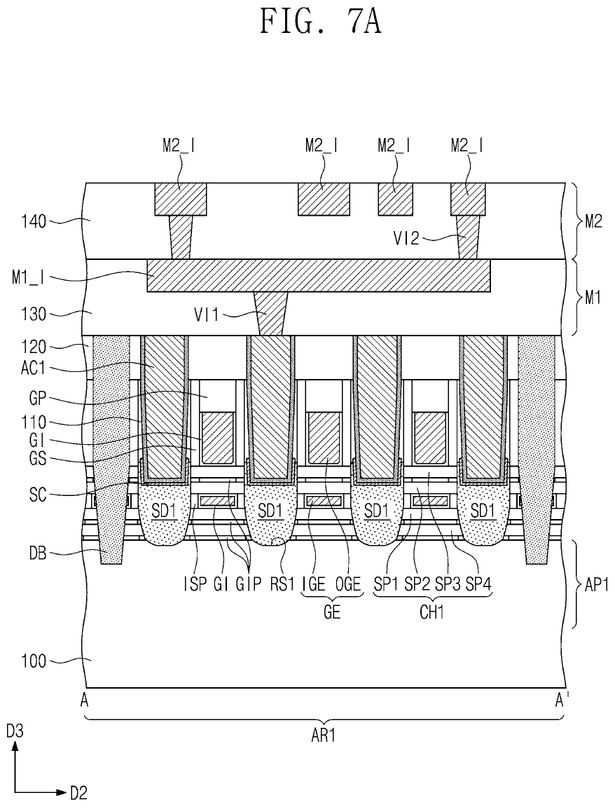

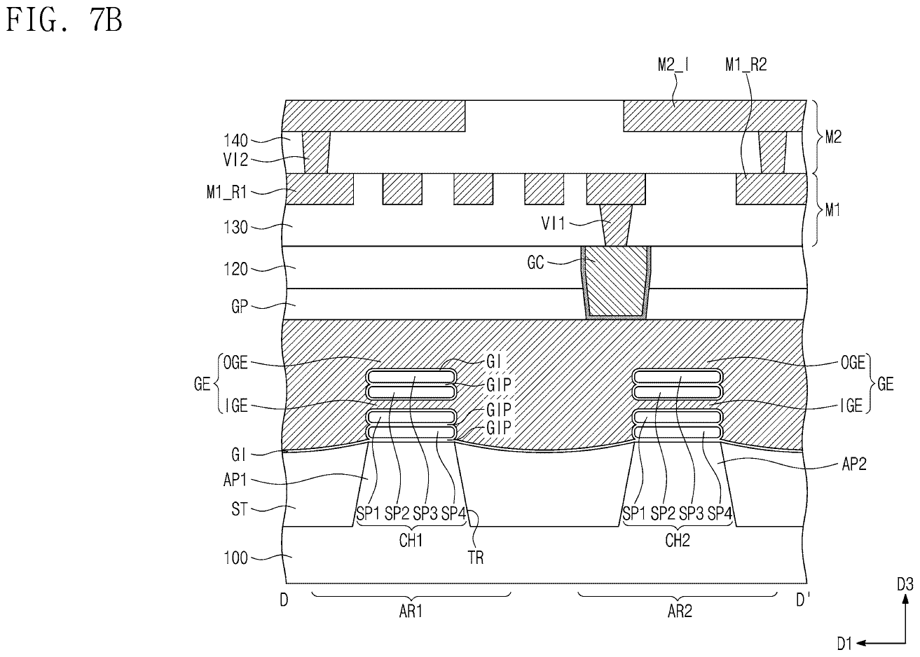

FIGS. 7A and 7B are diagrams illustrating a semiconductor device according to embodiments of the inventive concept, and are cross-sectional views taken along line A-A′ and line D-D′ in FIG. 4.

Hereinafter, for convenience of description, description of the same matters as those described with reference to FIG. 4 and FIGS. 5A to 5D will be omitted, and differences will be described in detail.

Referring to FIGS. 7A and 7B, each of the first multi-channel layer CH1 and the second multi-channel layer CH2 may further include a fourth channel layer SP4 located below the first channel layer SP1. For example, the fourth channel layer SP4 of the first multi-channel layer CH1 may be located between the first well region AP1 and the first channel layer SP1. The fourth channel layer SP4 of the second multi-channel layer CH2 may be located between the second well region AP2 and the first channel layer SP1.

The gate insulating layers GIP may be provided between the first multi-channel layer CH1 and the first well region AP1, between the second multi-channel layer CH2 and the second well region AP2, and between the first to fourth channel layers SP1, SP2, SP3, and SP4 of the first and second multi-channel layers CH1 and CH2. For example, each of the gate insulating layers GIP may be located between the first well region AP1 and the fourth channel layer SP4 of the first multi-channel layer CH1, between the second well region AP2 and the fourth channel layers SP4 of the second multi-channel layer CH2, between the first channel layer SP1 and the fourth channels layer SP4 of each of the first and second multi-channel layers CH1 and CH2, and between the second channel layer SP2 and the third channel layer SP3 of each of the second and first multi-channel layers CH1 and CH2. That is, the gate insulating layers GIP may not be provided between the first channel layer SP1 and the second channel layer SP2 of each of the first and second multi-channel layers CH1 and CH2.

The inner electrode IGE of the gate electrode GE may be located between the first channel layer SP1 and the second channel layer SP2 of each of the first and second multi-channel layers CH1 and CH2. The first and fourth channel layers SP1 and SP4 of the first multi-channel layer CH1 may be located between the inner electrode IGE and the first well region AP1. The first and fourth channel layers SP1 and SP4 of the second multi-channel layer CH2 may be located between the inner electrode IGE and the second well region AP2. Accordingly, the inner electrode IGE of the gate electrode GE may be further spaced apart from the first well region AP1 and the second well region AP2 in the third direction D3. Therefore, a phenomenon of punch through and DIBL (Drain Induced Barrier Lowering) between the first source/drain patterns SD1 and between the second source/drain pattern SD2 occurring on the first well region AP1 and the second well region AP2 may be prevented.

An interval between the first channel layer SP1 and the fourth channel layer SP4 of each of the first and second multi-channel layers CH1 and CH2 may be the first thickness T1 of the first and the second gate insulating layers GIP1 and GIP2 described with reference to FIGS. 6A and 6B. An interval between the first channel layer SP1 and the second channel layer SP2 of each of the first and second multi-channel layers CH1 and CH2 may be the fourth thickness T4 of the inner electrode IGE and the gate insulating film GI described with reference to FIGS. 6A and 6B. An interval between the second channel layer SP2 and the third channel layer SP3 of each of the first and second multi-channel layers CH1 and CH2 may be substantially the same as the interval between the first channel layer SP1 and the fourth channel layer SP4. That is, at least one of the intervals between the first to fourth channel layers SP1, SP2, SP3, and SP4 of each of the first and second multi-channel layers CH1 and CH2 may differ from the others.

The gate electrode GE may be located on side surfaces of the fourth channel layer SP4 of each of the first and second multi-channel layers CH1 and CH2. The fourth channel layer SP4 of each of the first and second multi-channel layers CH1 and CH2 may not function as a channel of the transistor unlike the first to third channel layers SP1, SP2, and SP3. However, the inventive concept is not limited thereto.

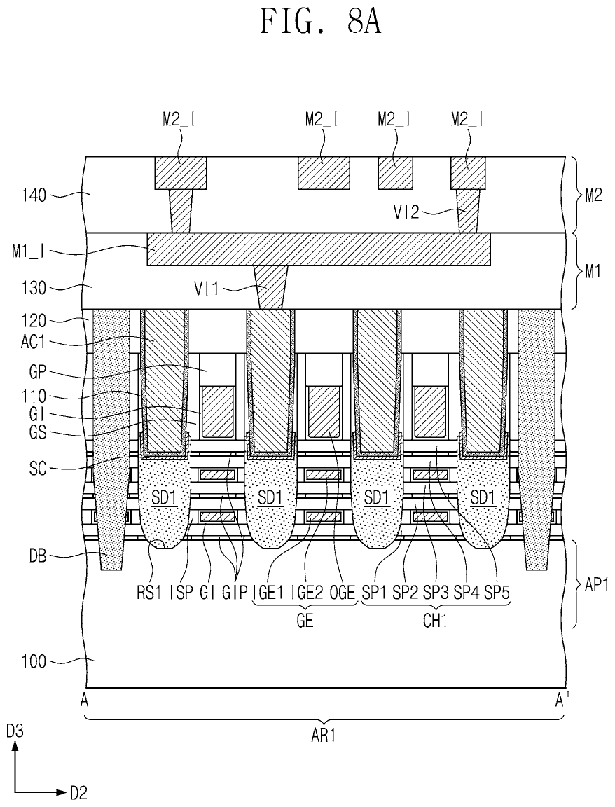

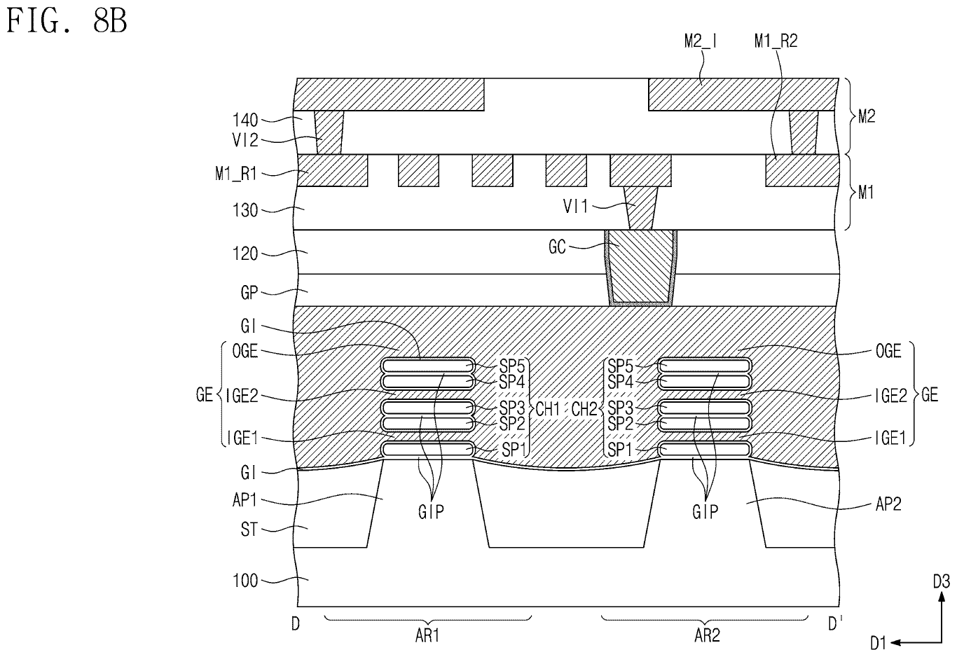

FIGS. 8A and 8B are diagrams illustrating a semiconductor device according to embodiments of the inventive concept, and are cross-sectional views taken along line A-A′ and line D-D′ in FIG. 4.

Hereinafter, for convenience of description, description of the same matters as those described with reference to FIG. 4 and FIGS. 5A to 5D will be omitted, and differences will be described in detail.

Referring to FIGS. 8A and 8B, each of the first multi-channel layer CH1 and the second multi-channel layer CH2 may further include a fourth channel layer SP4 and a fifth channel layer SP5, which are sequentially located on the third channel layer SP3. For example, the fourth and fifth channel layers SP4 and SP5 of each of the first and second multi-channel layers CH1 and CH2 may be located between the third channel layer SP3 and the outer electrode OGE of the gate electrode GE.

The gate insulating layers GIP may be provided between the first multi-channel layer CH1 and the first well region AP1, between the second multi-channel layer CH2 and the second well region AP2, and between the first to fifth channel layers SP1, SP2, SP3, SP4, and SP5 of the first and second multi-channel layers CH1 and CH2. For example, each of the gate insulating layers GIP may be positioned between the first well region AP1 and the first channel layer SP1 of the first multi-channel layer CH1, between the second well region AP2 and the first channel layers SP1 of the second multi-channel layer CH2, between the second channel layer SP2 and the third channel layer SP3 of each of the first and second multi-channel layers CH1 and CH2, and between the fourth channel layer SP4 and the fifth channel layer SP5 of each of the second and first multi-channel layers CH1 and CH2. That is, the gate insulating layers GIP may not be provided between the first channel layer SP1 and the second channel layer SP2 and between the third channel layer SP3 and the fourth channel layer SP4 of each of the first and second multi-channel layers CH1 and CH2.

The gate electrode GE may include a first inner electrode IGE1, a second inner electrode IGE2 on the first inner electrode IGE1, and an outer electrode OGE on the second inner electrode IGE2. The first inner electrode IGE1, the second inner electrode IGE2, and the outer electrode OGE may be spaced apart from one another in the third direction D3. For example, the first inner electrode IGE1 may be located between the first channel layer SP1 and the second channel layer SP2 of each of the first and second multi-channel layers CH1 and CH2. The second inner electrode IGE2 may be located between the third channel layer SP3 and the fourth channel layer SP4 of each of the first and second multi-channel layers CH1 and CH2. The outer electrode OGE may be located on the fifth channel layer SP5 of each of the first and second multi-channel layers CH1 and CH2.

In other words, the gate electrode GE may be located on the top and side surfaces of the first channel layer SP1 of each of the first and second multi-channel layers CH1 and CH2. The gate electrode GE may be located on the bottom and side surfaces of the second channel layer SP2 of each of the first and second multi-channel layers CH1 and CH2. The gate electrode GE may be located on the top and side surfaces of the third channel layer SP3 of each of the first and second multi-channel layers CH1 and CH2. The gate electrode GE may be located on a bottom and side surfaces of the fourth channel layer SP4 of each of the first and second multi-channel layers CH1 and CH2. The gate electrode GE may be located on a top and side surfaces of the fifth channel layer SP5 of each of the first and second multi-channel layers CH1 and CH2. That is, the gate electrode GE may be located on three surfaces of each of the first to fifth channel layers SP1, SP2, SP3, SP4, and SP5 of each of the second and first multi-channel layers CH1 and CH2. The gate electrode GE may control the first and second multi-channel layers CH1 and CH2 through the three surfaces of each the first to fifth channels layers SP1, SP2 and SP3 and SP4 and SP5.

An interval between the second channel layer SP2 and the third channel layer SP3 of each of the first and second multi-channel layers CH1 and CH2 may be the first thickness T1 of the first and the second gate insulating layers GIP1 and GIP2 described with reference to FIGS. 6A and 6B. An interval between the first channel layer SP1 and the second channel layer SP2 of each of the first and second multi-channel layers CH1 and CH2 may be the fourth thickness T4 of the inner electrode IGE and the gate insulating film GI described with reference to FIGS. 6A and 6B. An interval between the fourth channel layer SP4 and the fifth channel layer SP5 of each of the first and second multi-channel layers CH1 and CH2 may be substantially the same as the interval between the second channel layer SP2 and the third channel layer SP3. An interval between the third channel layer SP3 and the fourth channel layer SP4 of each of the first and second multi-channel layers CH1 and CH2 may be substantially the same as the interval between the first channel layer SP1 and the second channel layer SP2. That is, at least one of the intervals between the first to fifth channel layers SP1, SP2, SP3, SP4, or SP5 of each of the first and second multi-channel layers CH1 and CH2 may differ from the others.

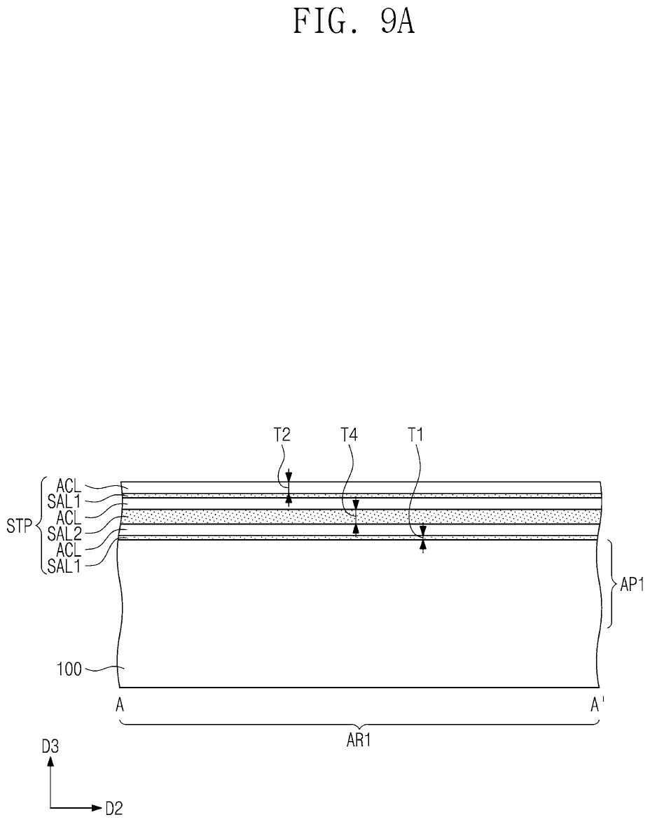

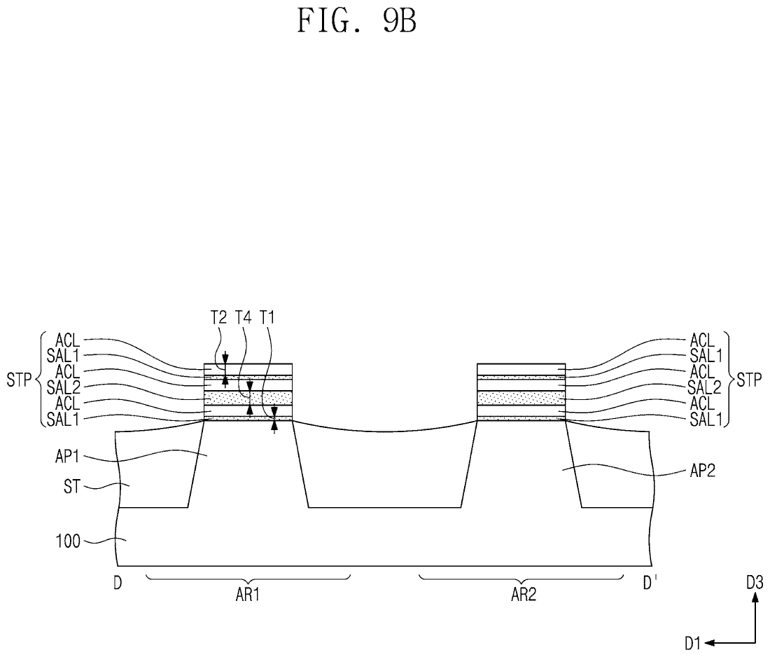

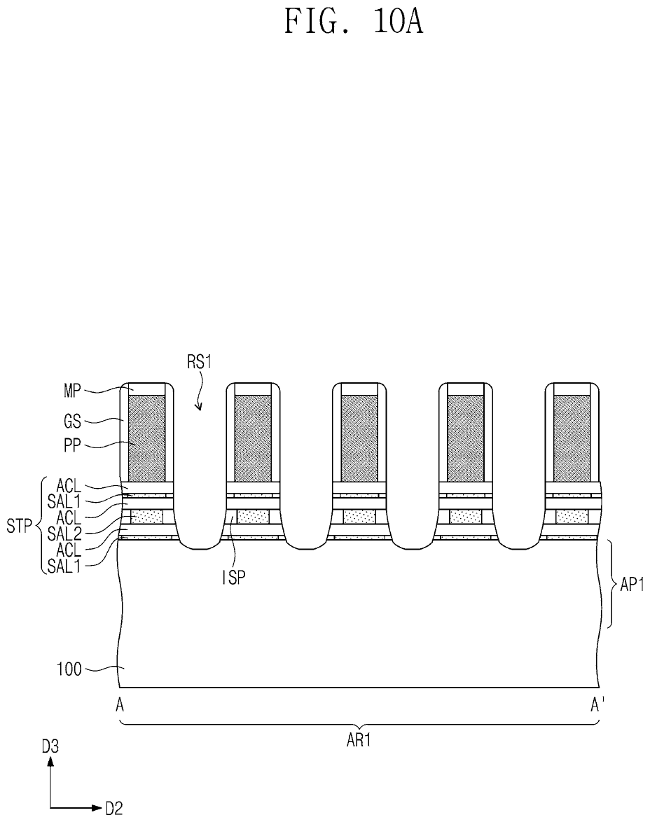

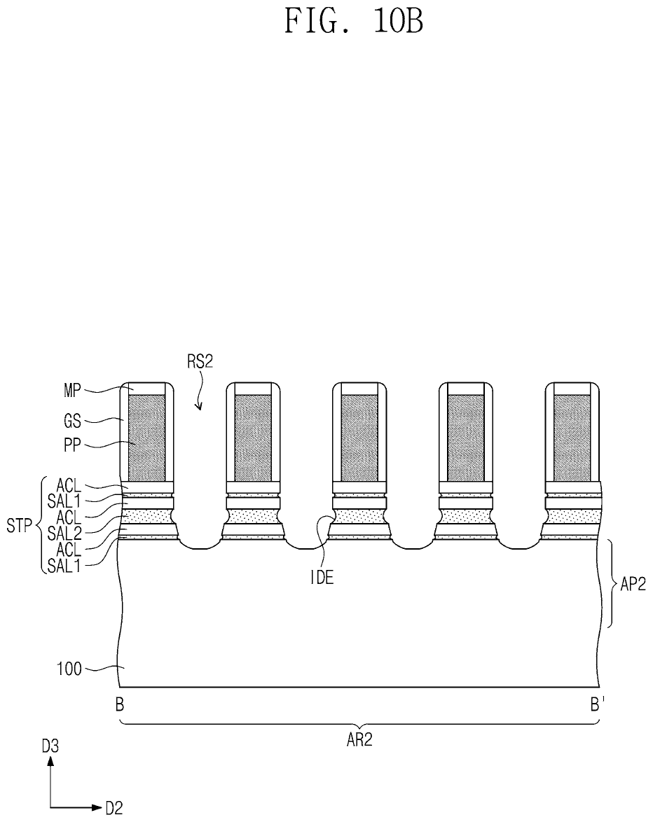

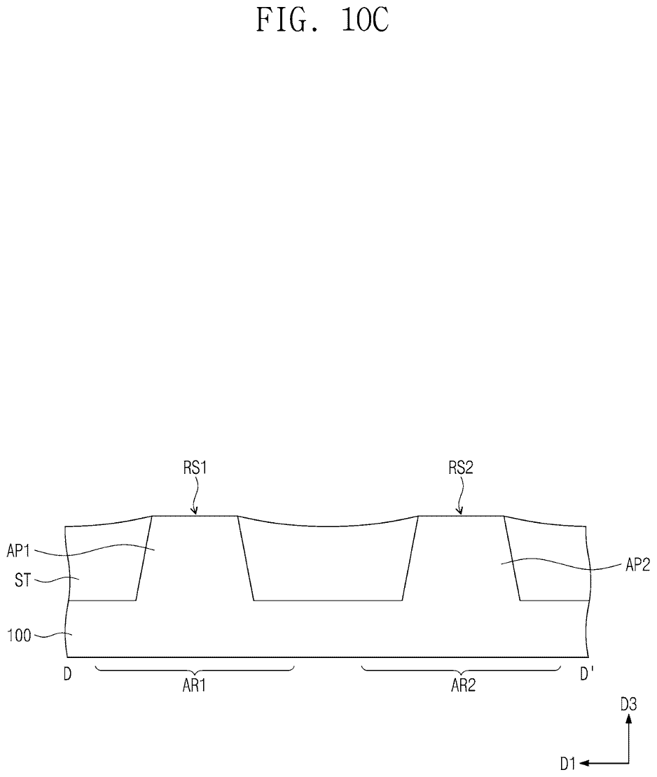

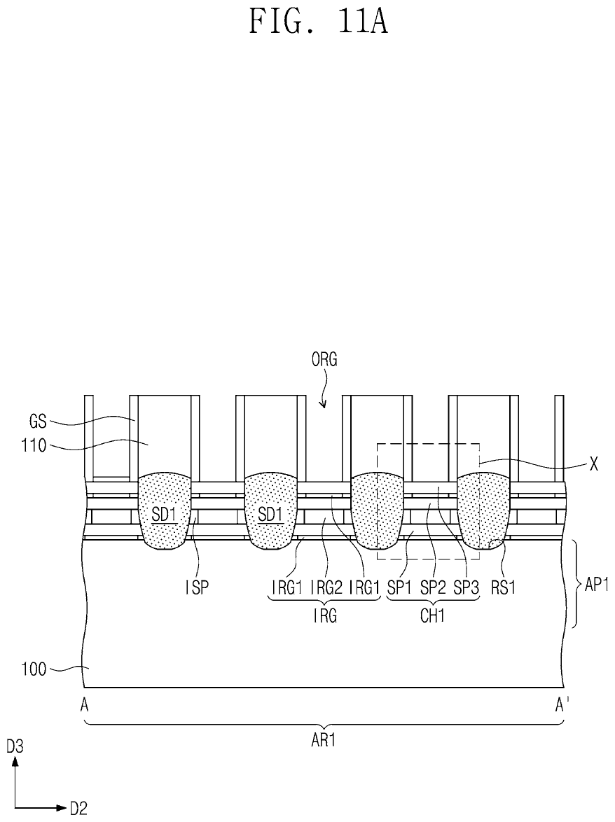

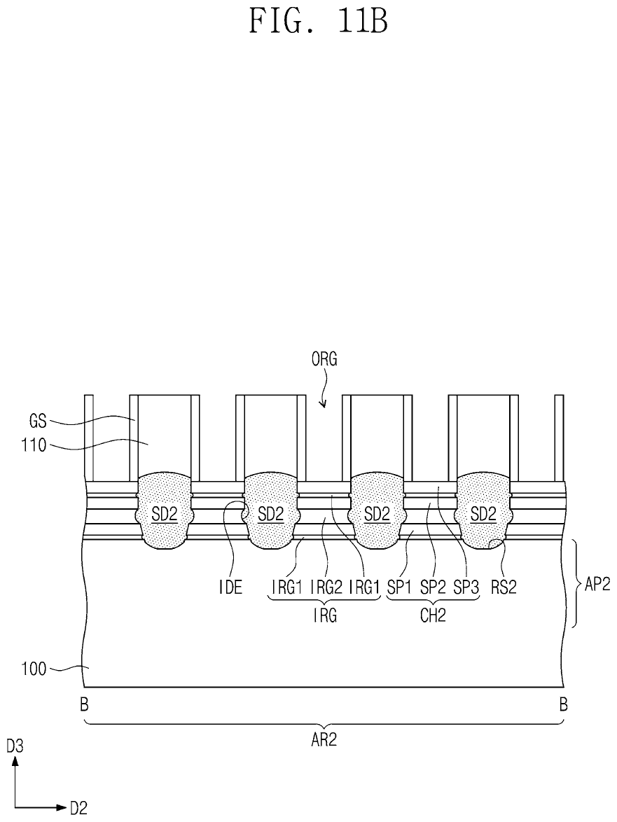

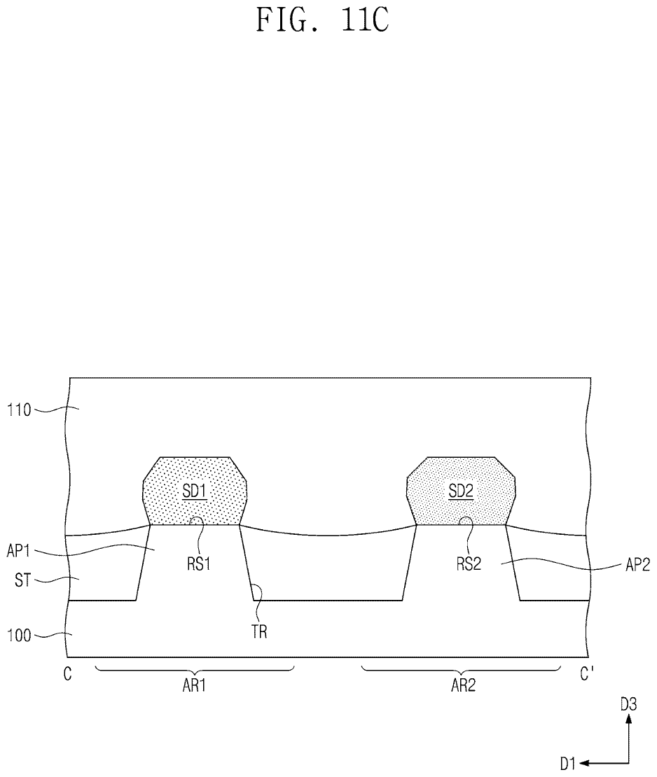

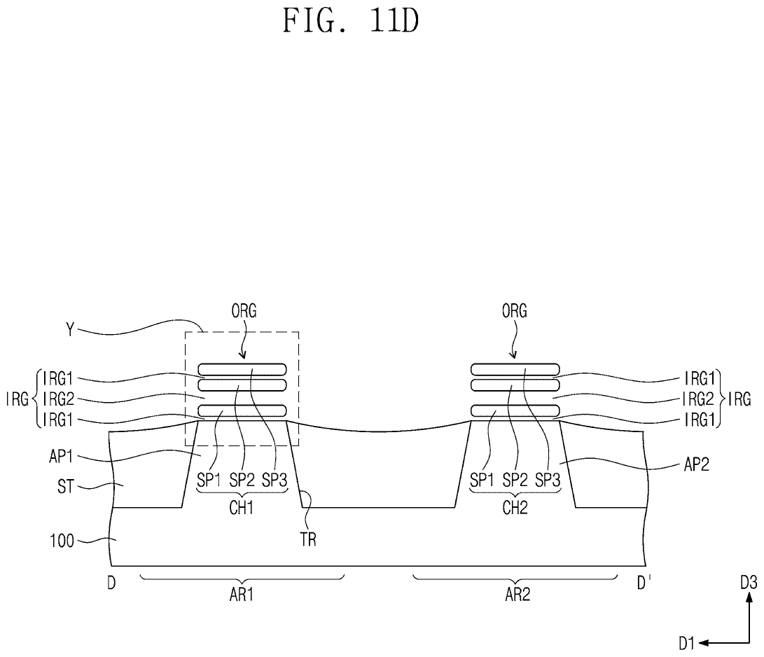

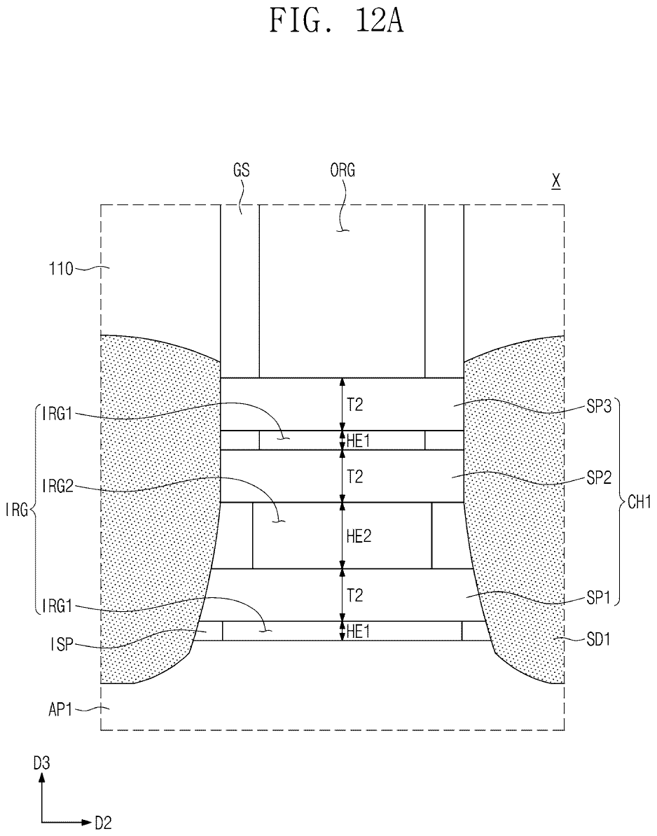

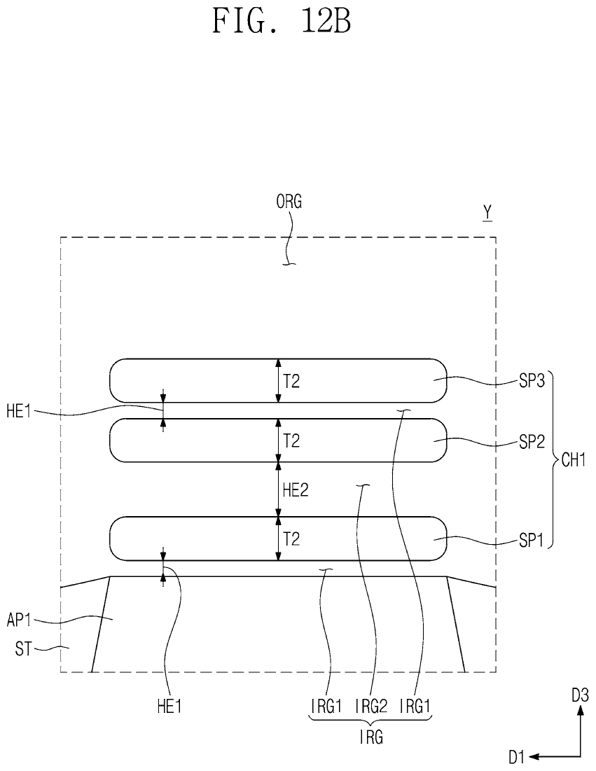

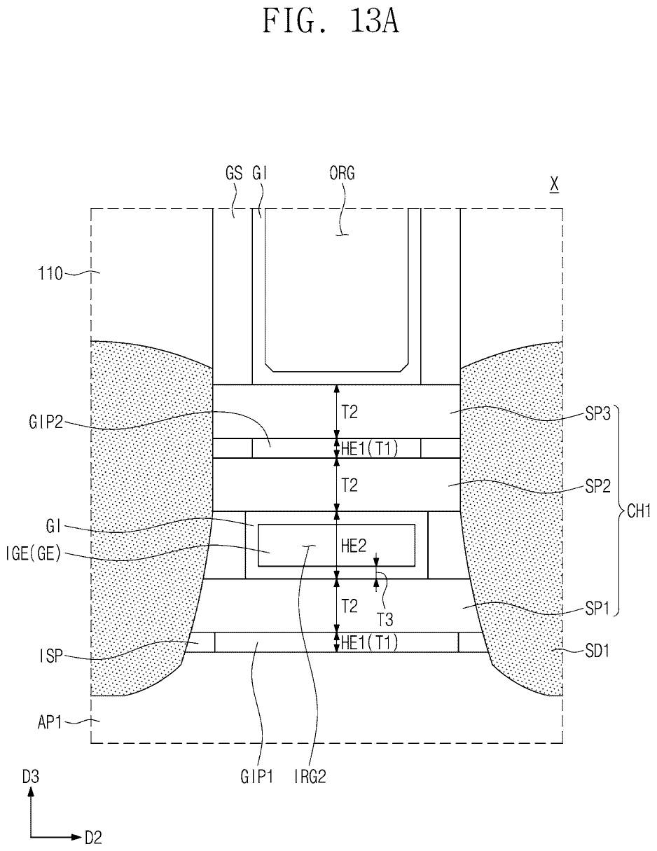

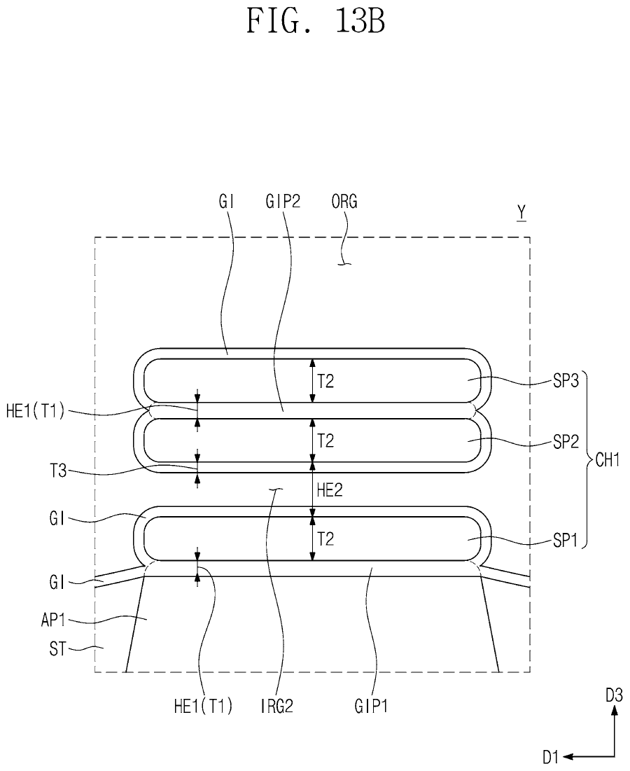

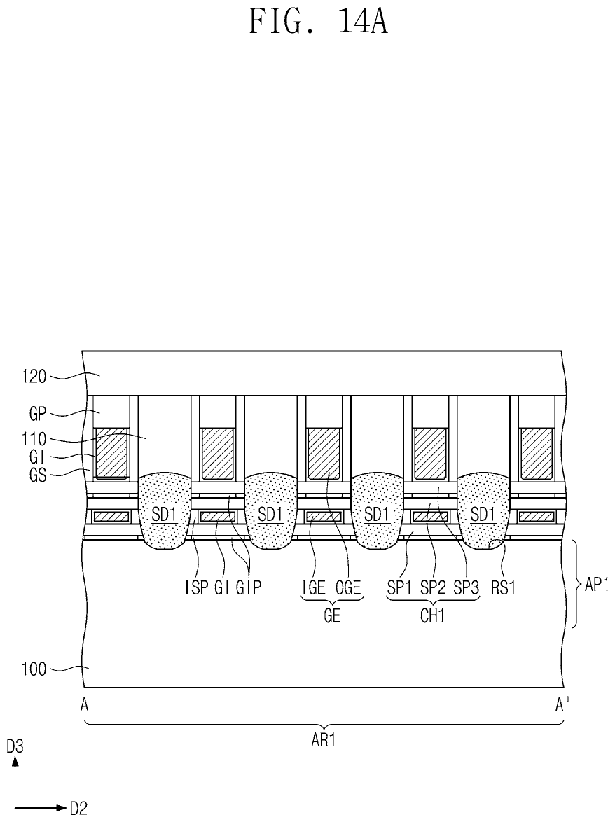

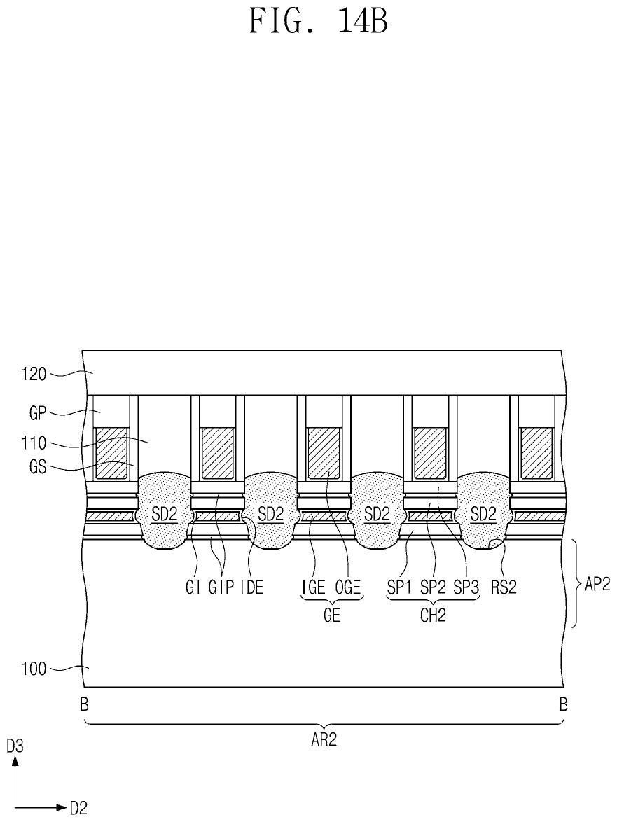

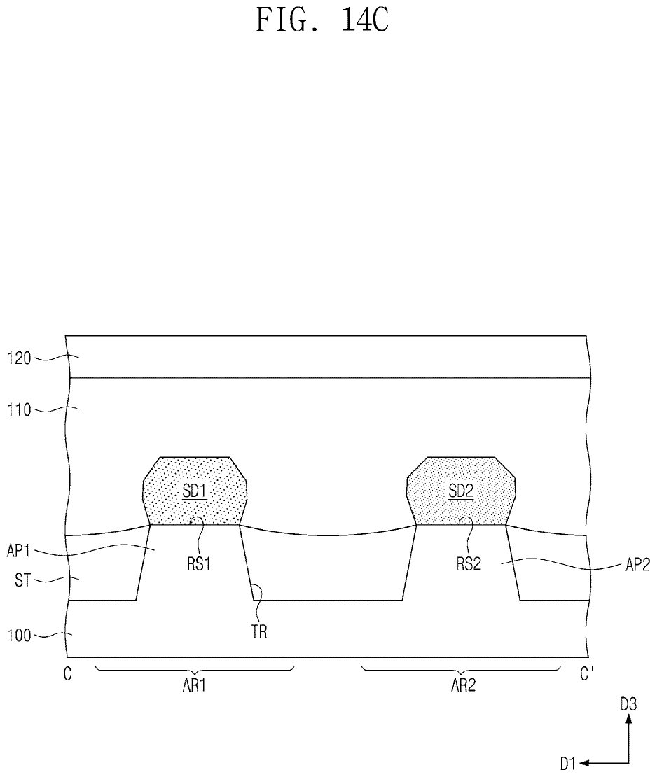

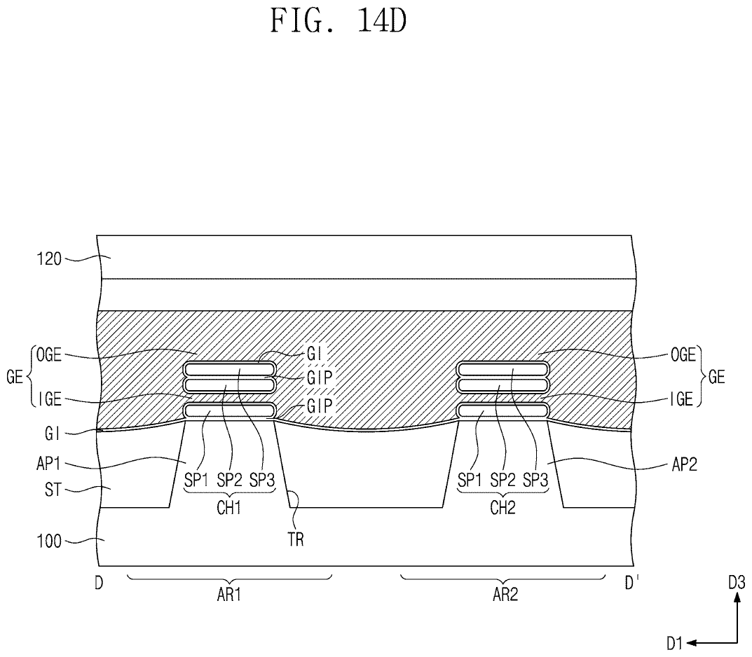

FIGS. 9A to 14D are diagrams for describing a method of manufacturing a semiconductor device according to embodiments of the inventive concept. FIGS. 9A, 10A, 11A, and 14A are taken along line A-A′ of FIG. 4. FIGS. 10B, 11B, and 14B are taken along line B-B′ of FIG. 4. FIGS. 11C and 14C are taken along line C-C′ of FIG. 4. FIGS. 9B, 10C, 11D, and 14D are taken along line D-D′ of FIG. 4. FIGS. 12A and 13A are enlarged views of the X portion of FIG. 11A. FIGS. 12B and 13B are enlarged views of the Y portion of FIG. 11D.

Referring to FIGS. 9A and 9B, a substrate 100 including a first active region AR1 and a second active region AR2 may be provided. Active layers ACL, first sacrificial layers SAL1, and second sacrificial layer SAL2 may be formed on the substrate 100. The active layers ACL may be spaced apart from each other and vertically overlap each other on the substrate 100. Each of the first sacrificial layers SAL1 and the second sacrificial layer SAL2 may be located between the active layers ACL. The second sacrificial layer SAL2 may be located between the first sacrificial layers SAL1. The lower one of the first sacrificial layers SAL1 may be located between the substrate 100 and the lowermost one of the active layers ACL. For example, the active layers ACL and the sacrificial layers may be alternately stacked on the substrate 100.

Each of the first sacrificial layers SAL1 may have a first thickness T1 in a third direction D3. Each of the active layers ACL may have a second thickness T2 in the third direction D3. The second sacrificial layer SAL2 may have a fourth thickness T4 in the third direction D3. The first thickness T1 of each of the first sacrificial layers SAL1 may be substantially the same as the first thickness T1 of each of the first and second gate insulating layers GIP1 and GIP2 described with reference to FIGS. 6A and 6B. The second thickness T2 of each of the active layers ACL may be substantially the same as the second thickness T2 of each of the first to third channel layers SP1, SP2, and SP3 described with reference to FIGS. 6A and 6B. The fourth thickness T4 of the second sacrificial layer SAL2 may be substantially the same as the fourth thicknesses T4 of the inner electrode IGE and the gate insulating film GI described with reference to FIGS. 6A and 6B.

However, the inventive concept is not limited thereto. The active layers ACL, the first sacrificial layers SAL1, and the second sacrificial layer SAL2 may be variously provided to form the first and second multi-channel layers CH1 and CH2 described with reference to FIGS. 7A to 8B.

The first and second sacrificial layers SAL1 and SAL2 may include a material having an etch selectivity with respect to the active layers ACL. The active layers ACL may include one of silicon, germanium, and silicon-germanium, and the first and second sacrificial layers SAL1 and SAL2 may include the other of silicon, germanium, and silicon-germanium. For example, the active layers ACL may include silicon, and the first and second sacrificial layers SAL1 and SAL2 may include silicon-germanium. A concentration of germanium in the first and second sacrificial layers SAL1 and SAL2 may be from about 10 at % to about 30 at %.

Mask patterns may be formed on the first and second active regions AR1 and AR2 of the substrate 100, respectively. The mask pattern may have a line shape or a bar shape extending in a second direction D2.

A trench TR defining a first well region AP1 and a second well region AP2 may be formed by performing a patterning process using the mask patterns as an etching mask. The first well region AP1 may be formed on the first active region AR1. The second well region AP2 may be formed on the second active region AR2.

A stacking pattern STP may be formed on each of the first and second well regions AP1 and AP2. The stacking pattern STP may include the active layers ACL, and the first sacrificial layers SAL1 and the second sacrificial layer SAL2 between the active layers ACL. The stacking pattern STP may be formed together with the first and second well regions AP1 and AP2 by the patterning process.

A device isolation layer ST filling the trench TR may be formed. Specifically, an insulating layer covering the first and second well regions AP1 and AP2 and the stacked pattern STP may be formed on a top surface of the substrate 100. The insulating layer may be recessed until the stacking pattern STP exposed, and the device isolation layer ST may be formed. Accordingly, the stacking pattern STP may protrude from the device isolation layer ST in the third direction D3. For example, the device isolation layer ST may include an insulating material such as silicon oxide.

Referring to FIGS. 10A, 10B, and 10C, sacrificial patterns PP crossing the stacking pattern STP may be formed on the substrate 100. Each of the sacrificial patterns PP may be formed in a line shape or a bar shape extending in a first direction D1. The sacrificial patterns PP may be spaced apart from each other in the second direction D2.

Forming the sacrificial patterns PP may include forming a sacrificial layer on the top surface of the substrate 100, forming hard mask patterns MP on the sacrificial layer, and patterning the sacrificial layer using the hard mask patterns MP as an etch mask. The sacrificial layer may include polysilicon.

A pair of gate spacers GS may be formed on both sidewalls of each of the sacrificial patterns PP. Forming the gate spacers GS may include forming a gate spacer layer with a uniform thickness on the top surface of the substrate 100, and anisotropic etching the gate spacer layer. For example, the gate spacers GS may be formed of a multilayer structure.

Thereafter, first recesses RS1 may be formed in the stacking pattern STP on the first well region AP1. Second recesses RS2 may be formed in the stacking pattern STP on the second well region AP2. Forming the first and second recesses RS1 and RS2 may include removing a portion of the stacked pattern STP with an etch process using the hard mask patterns MP and the gate spacers GS as an etch mask. Each of the first and second recesses RS1 and RS2 may be formed between a pair of sacrificial patterns PP.

The first and second sacrificial layers SAL1 and SAL2 may be exposed by the first and second recesses RS1 and RS2. The exposed first and second sacrificial layers SAL1 and SAL2 may be partially removed by an etching process. Accordingly, the first and second sacrificial layers SAL1 and SAL2 may be indented to form indent regions IDE. For example, the indented regions IDE of the second sacrificial layer SAL2 may be greater than the indented region IDE of the first sacrificial layers SAL1.

Inner spacers ISP may be formed on the first active region AR1 to fill the indent regions IDE. Alternatively, the inner spacers ISP may not be formed on the second active region AR2. Accordingly, each of the second recesses RS2 may have an inner sidewall with a wavy profile.

Referring to FIGS. 11A, 11B, 11C, and 11D, first source/drain patterns SD1 may be formed in the first recesses RS1, respectively. For example, an epitaxial layer filling the first recesses RS1 may be formed by performing an SEG process in which an inner sidewall of the first recess RS1 used as a seed layer. The epitaxial layer may be grown with the active layers ACL and the first well region AP1 exposed by the first recesses RS1 as seed. For example, the SEG process may include a chemical vapor deposition (CVD) process or a molecular beam epitaxy (MBE) process.

The first source/drain patterns SD1 may include A same semiconductor element (e.g., Si) as the substrate 100. While the first source/drain patterns SD1 are formed, an impurity (e.g., phosphorus, arsenic, or antimony) may be in-situ implanted to allow the first source/Drain patterns SD1 to have an n-type conductivity. Alternatively, the impurity may be implanted into the first source/drain patterns SD1 after the first source/drain patterns SD1 are formed.

Second source/drain patterns SD2 may be formed in the second recesses RS2, respectively. For example, forming the second source/drain patterns SD2 may be substantially the same as forming the first source/drain pattern SD1. The second source/drain patterns SD2 may include a semiconductor element (e.g., SiGe) having a lattice constant greater than that of the semiconductor element of the substrate 100. While the second source/drain patterns SD2 are formed, an impurity (e.g., boron, gallium, or indium) may be in-situ implanted to allow the second source/drain patterns SD2 to have a p-type conductivity. Alternatively, the impurity may be implanted into the second source/drain patterns SD2 after the second source/drain patterns SD2 are formed.

Then, the first interlayer insulating layer 110 may be formed on the top surface of the substrate 100. The first interlayer insulating layer 110 may cover the first source/drain patterns SD1, the second source/drain pattern SD2, the hard mask patterns MP, and the gate spacers GS. For example, the first interlayer insulating layer 110 may include an insulating material such as silicon oxide.

The first interlayer insulating layer 110 may be planarized until top surfaces of the sacrificial patterns PP are exposed. The planarization of the first interlayer insulating layer 110 may be performed using an Etch-Back or a CMP (Chemical Mechanical Polishing) process. During the planarization process, the hard mask patterns MP may be removed. Therefore, a top surface of the first interlayer insulating layer 110 may be coplanar with the top surfaces of the sacrificial patterns PP and top surfaces of gate spacers GS.

After the planarization process, the sacrificial patterns PP may be selectively removed. By removing the sacrificial patterns PP, an outer region ORG exposing the first and second sacrificial layers SAL1 and SAL2 may be formed. Removing the sacrificial patterns PP may include wet etching using an etchant that selectively removes polysilicon.

The first and second sacrificial layers SAL1 and SAL2 exposed through the outer region ORG may be selectively removed. The first and second sacrificial layers SAL1 and SAL2 may be removed only and the active layers ACL may remain using an etching process of selectively etching the first and second sacrificial layers SAL1 and SAL2. Each of the remaining active layers ACL may be formed of first to third channel layers SP1, SP2, and SP3. A first multi-channel layer CH1 including first to third channel layers SP1, SP2, and SP3 may be formed on the first well region AP1. A second multi-channel layer CH2 including first to third channel layers SP1, SP2, and SP3 may be formed on the second well region AP2.

Referring to FIGS. 12A and 12B, the first and second sacrificial layers SAL1 and SAL2 may be removed to form first and second inner regions IRG1 and IRG2. The first inner regions IRG1 may be formed in a region where the first sacrificial layers SAL1 are removed. The second inner region IRG2 may be formed in a region where the second sacrificial layer SAL2 is removed. For example, each of the first inner regions IRG1 may be located between the first and second well regions AP1 and AP2 and the first channel layer SP1 of each of the first and second multi-channel layers CH1 and CH2, and between the second channel layer SP2 and the third channel layer SP3 of each of the second and first multi-channel layers CH1 and CH2. The second inner region IRG2 may be located between the first channel layer SP1 and the second channel layer SP2 of each of the first and second multi-channel layers CH1 and CH2.

Each of the first inner regions IRG1 may have a first height HE1 that is substantially the same as the first thickness T1 of the first sacrificial layers SAL1 described with reference to FIGS. 9A and 9B. The second inner region IRG2 may have a second height HE2 that is substantially the same as the fourth thickness T4 of the second sacrificial layer SAL2 described with reference to FIGS. 9A and 9B. Each of the first to third channel layers SP1, SP2, and SP3 of the first multi-channel layer CH1 may have a second thickness T2 that is substantially the same as the second thickness T2 of the active layers ACL described with reference to FIGS. 9A and 9B. The first height HE1 of each of the first inner regions IRG1 may be less than the second height HE2 of the second inner region IRG2.

The second height HE2 of the second inner region IRG2 may be an interval between the first channel layer SP1 and the second channel layer SP2. The first height HE1 of the first inner region IRG1 may be an interval between the second channel layer SP2 and the third channel layer SP3. That is, the interval between the first channel layer SP1 and the second channel layer SP2 may be greater than the interval between the second channel layer SP2 and the third channel layer SP3. For example, an interval between the first well region AP1 and the first channel layer SP1 and the interval between the second channel layer SP2 and the third channel layer SP3 may be relatively small.

Referring to FIGS. 13A and 13B, gate insulating film GI may be formed on the first to third channel layers SP1, SP2, and SP3 exposed by the first and second inner regions IRG1 and IRG2 and the outer region ORG. The gate insulating film GI may be formed to have a third thickness T3. For example, the gate insulating film GI may cover top and side surfaces of the first channel layer SP1. The gate insulating film GI may cover bottom and side surfaces of the second channel layer SP2. The gate insulating film GI may cover top and side surfaces of the third channel layer SP3.

The first height HE1 of each of the first inner regions IRG1 may not be sufficient for the gate insulating film GI to surround the first inner region IRG1 with the third thickness T3. For example, the first height HE1 of each of the first inner regions IRG1 may be greater than the third thickness T3 of the gate insulating film GI and less than or equal to twice the third thickness T3. Therefore, a portion of the gate insulating film GI covering a top surface of the first well region AP1 and another portion of the gate insulating film GI covering a bottom surface of the first channel layer SP1 may be in contact with each other to form a first gate insulating layer GIP1. A portion of the gate insulating film GI covering a top surface of the second channel layer SP2 and another portion of the gate insulating film GI covering a bottom surface of the third channel layer SP3 may be in contact with each other to form a second gate insulating layer GIP2. The first gate insulating layer GIP1 may have a first thickness T1 between the first well region AP1 and the first channel layer SP1. The second gate insulating layer GIP2 may have a first thickness T1 between the second channel layer SP2 and the third channel layer SP3.

The second height HE2 of the second inner region IRG2 may be sufficient for the gate insulating film GI to surround the second inner region IRG2 with the third thickness T3. For example, the second height HE2 of the second inner region IRG2 may be greater than twice the third thickness T3 of the gate insulating film GI. Therefore, a portion of the gate insulating film GI covering the top surface of the first channel layer SP1 and another portion of the gate insulating film GI covering the bottom surface of the second channel layer SP2 may be spaced apart from each other in the third direction D3. That is, the gate insulating film GI may not completely fill the second inner region IRG2.

In other words, forming the gate insulating film GI may include forming the first gate insulating layer GIP1 between the first well region AP1 and the first channel layer SP1 and forming the second gate insulating layer GIP2 between the second channel layer SP2 and the third channel layer SP3. For example, the gate insulating film GI and the first and second gate insulating layers GIP1 and GIP2 may be simultaneously formed. Accordingly, a method of manufacturing a semiconductor device may be simplified.

Referring to FIGS. 14A, 14B, 14C, and 14D, a gate electrode GE may be formed on the gate insulating film GI. Forming the gate electrode GE may include forming an inner electrode IGE filling the second inner region IRG2 and forming an outer electrode OGE filling the outer region ORG.

Thereafter, the outer electrode OGE of the gate electrode GE may be recessed. For example, a top surface of the outer electrode OGE of the gate electrode GE may be recessed until it becomes lower than that of the first interlayer insulating layer 110.

Gate capping patterns GP may be formed on the gate electrode GE. Top surfaces of the gate capping patterns GP may be coplanar with the top surface of the first interlayer insulating layer 110. For example, the gate capping patterns GP may include an insulating material such as silicon nitride.

A second interlayer insulating layer 120 may be formed on the first interlayer insulating layer 110. The second interlayer insulating layer 120 may cover the first interlayer insulating layer 110 and the gate capping patterns GP. For example, the second interlayer insulating layer 120 may include substantially the same insulating material as the first interlayer insulating layer 110.

Referring again to FIGS. 5A, 5B, 5C, and 5D, first and second active contacts AC1 and AC2 may be formed to penetrate the second interlayer insulating layer 120 and the first interlayer insulating layer 110 to come into electrically connection with the first and second source/drain patterns SD1 and SD2. Gate contacts GC may be formed to penetrate the second interlayer insulating layer 120 and the gate capping patterns GP to come into electrically connection with the gate electrodes GE.

Forming the gate contacts GC and the first and second active contacts AC1 and AC2 may include forming a barrier pattern and forming a conductive pattern on the barrier pattern. The barrier pattern may be formed with a uniform thickness and may include a metal or metal nitride. The conductive pattern may include a low resistance metal.

Then, a pair of separation structures DB may be formed to extend from the second interlayer insulating layer 120 toward the upper portions of the first and second well regions AP1 and AP2. A third interlayer insulating layer 130 may be formed on the first and second active contacts AC1 and AC2 and the gate contacts GC. The first metal layer M1 may be formed in the third interlayer insulating layer 130. A fourth interlayer insulating layer 140 may be formed on the third interlayer insulating layer 130. The second metal layer M2 may be formed in the fourth interlayer insulating layer 140.

A semiconductor device according to embodiments of the inventive concept may include a gate electrode that is further spaced from a well region than a channel layer. A phenomenon of punch through and DIBL (Drain Induced Barrier Lowering) between source/drain patterns occurring on the well region may be prevented. In addition, the gate electrode may include a minimum inner electrode for controlling channel layers. A parasitic capacitance between the gate electrode and other configurations may be reduced. Accordingly, electrical characteristics of the semiconductor device may be improved.

A method of manufacturing a semiconductor device according to an embodiment of the inventive concept may include forming a stacked pattern including active layers and sacrificial layers alternately stacked on a substrate; forming source/drain patterns in a recess penetrating the stacked pattern; selectively removing the sacrificial layer of the stacked pattern; forming a gate insulating layer on first to third channel layers formed from the active layers; and forming a gate electrode on the gate insulating layer, wherein the sacrificial layers include first sacrificial layers and a second sacrificial layer between the first sacrificial layers, and a thickness of the second sacrificial layer is greater than a thickness of each of the first sacrificial layers.

In the method of manufacturing a semiconductor device according to an embodiment, forming the gate insulating layer may include forming a first gate insulating layer and a second gate insulating layer.

In method of manufacturing a semiconductor device according to an embodiment, the first gate insulating layer may be formed between the substrate and the first channel layer.

In method of manufacturing a semiconductor device according to an embodiment, the second insulating layer may be formed between the second channel layer and the third channel layer.

In method of manufacturing a semiconductor device according to an embodiment, forming the gate electrode may include forming an inner electrode between the first channel layer and the second channel layer and an outer electrode on the third channel layer.

While embodiments are described above, a person skilled in the art may understand that many modifications and variations are made without departing from the spirit and scope of the inventive concept defined in the following claims. Accordingly, the example embodiments of the inventive concept should be considered in all respects as illustrative and not restrictive, with the spirit and scope of the inventive concept being indicated by the appended claims.

What is claimed is:

1. A semiconductor device, comprising:
a well region in a substrate;
a multi-channel layer on the well region, the multi-channel layer including first, second, and third channel layers sequentially stacked in a vertical direction and spaced apart from one another;
a first gate insulating layer between the first channel layer and the well region; and
a gate electrode overlapping the multi-channel layer,
wherein the gate electrode comprises:
an inner electrode between the first channel layer and the second channel layer; and
an outer electrode on the third channel layer, and
wherein an interval between the well region and the first channel layer is less than an interval between the first channel layer and the second channel layer.

2. The semiconductor device of claim 1, wherein the inner electrode of the gate electrode is further spaced apart from the well region than the first channel layer.

3. The semiconductor device of claim 1, wherein a thickness of the first gate insulating layer is less than the interval between the first channel layer and the second channel layer.

4. The semiconductor device of claim 1, further comprising:
a second gate insulating layer between the second channel layer and the third channel layer,
wherein the second gate insulating layer contacts the second channel layer and the third channel layer.

5. The semiconductor device of claim 4, wherein the first gate insulating layer and the second gate insulating layer have substantially the same thickness.

6. The semiconductor device of claim 1, further comprising:
a gate insulating film between the multi-channel layer and the gate electrode, and
wherein a thickness of the gate insulating film is different from a thickness of the first gate insulating layer.

7. The semiconductor device of claim 6, wherein the thickness of the first gate insulating layer is greater than the thickness of the gate insulating film and is less than or equal to twice the thickness of the gate insulating film.

8. The semiconductor device of claim 6, wherein the gate insulating film and the first gate insulating layer include the same insulating material, and
wherein an interface between the gate insulating film and the first gate insulating layer is invisible.

9. The semiconductor device of claim 1, wherein the interval between the first channel layer and the second channel layer is greater than an interval between the second channel layer and the third channel layer.

10. The semiconductor device of claim 1, wherein the multi-channel layer further includes a fourth channel layer between the well region and the first channel layer.

11. A semiconductor device, comprising:
a well region in a substrate;
a multi-channel layer on the well region, the multi-channel layer including a plurality of channel layers sequentially stacked in a vertical direction and spaced apart from one another, the plurality of channel layers including a first channel layer, which is a lowermost layer among the plurality of channel layers;
a first gate insulating layer between the well region and the first channel layer;
a gate electrode overlapping the multi-channel layer; and
a gate insulating film between the multi-channel layer and the gate electrode,
wherein at least one interval between the plurality of channel layers differs from remaining intervals between the plurality of channel layers.

12. The semiconductor device of claim 11, wherein the gate electrode comprises an inner electrode between the plurality of channel layers, and
wherein the inner electrode is on the first channel layer.

13. The semiconductor device of claim 11, wherein a thickness of the first gate insulating layer is greater than a thickness of the gate insulating film.

14. The semiconductor device of claim 11, wherein each of the plurality of channel layers is a two-dimensional semiconductor material including at least one of MoS₂, MoSe₂, WS₂, WSe₂, or Bi₂O₂Se.

15. The semiconductor device of claim 14, wherein a thickness of each of the plurality of channel layers is 0.5 nm to 3 nm.

16. The semiconductor device of claim 11, wherein the gate insulating film and the first gate insulating layer include the same material.

17. A semiconductor device, comprising:
a well region in a substrate;
a multi-channel layer on the well region and including first, second, and third channel layers sequentially stacked in a vertical direction and spaced apart from one another;
source/drain patterns on both sides of the multi-channel layer;
a gate electrode overlapping the multi-channel layer;
a gate insulating film between the multi-channel layer and the gate electrode;
a first gate insulating layer between the first channel layer and the well region; and
a second gate insulating layer between the second channel layer and the third channel layer,
wherein the gate electrode comprises:
an inner electrode between the first channel layer and the second channel layer; and
an outer electrode on the third channel layer, and
wherein an interval between the first channel layer and the second channel layer is greater than an interval between the second channel layer and the third channel layer.

18. The semiconductor device of claim 17, wherein the first gate insulating layer and the second gate insulating layer are thicker than the gate insulating film and have substantially the same thickness.

19. The semiconductor device of claim 17, wherein the first gate insulating layer contacts the first channel layer and the well region, and
wherein the second gate insulating layer contacts the second channel layer and the third channel layer.

20. The semiconductor device of claim 17, further comprising
inner spacers between the first gate insulating layer and the source/drain patterns and between the second gate insulating layer and the source/drain patterns.
